(19) United States
(12) Patent Application Publication
(10) Pub. No.: US 2013/0069158 A1
(43) Pub. Date: Mar. 21, 2013

(54) POWER SEMICONDUCTOR DEVICE

(71) Applicants: Hiroshi OHTA, Hyogo-ken (JP); Yasuto Sumi, Hyogo-ken (JP); Kiyoshi Kimura, Hyogo-ken (JP); Junji Suzuki, Hyogo-ken (JP); Hiroyuki Irifune, Hyogo-ken (JP); Wataru Saito, Kanagawa-ken (JP)

(72) Inventors: Hiroshi OHTA, Hyogo-ken (JP); Yasuto Sumi, Hyogo-ken (JP); Kiyoshi Kimura, Hyogo-ken (JP); Junji Suzuki, Hyogo-ken (JP); Hiroyuki Irifune, Hyogo-ken (JP); Wataru Saito, Kanagawa-ken (JP)

(73) Assignee: Kabushiki Kaisha Toshiba, Tokyo (JP)

(21) Appl. No.: 13/425,258

(22) Filed: Mar. 20, 2012

(30) Foreign Application Priority Data
Sep. 21, 2011 (JP) 2011-206341

(51) Int. Cl. H01L 29/78

(52) U.S. Cl. 257/342; 257/E29.257

(57) ABSTRACT

A power semiconductor device includes a high resistance epitaxial layer having a first pillar region and a second pillar region as a drift layer. The first pillar region includes a plurality of first pillars of the first conductivity type and a plurality of second pillars of the second conductivity type disposed alternately along a first direction. The second pillar region is adjacent to the first pillar region along the first direction. The second pillar region includes a third pillar and a fourth pillar of a conductivity type opposite to a conductivity type of the third pillar. A net quantity of impurities in the third pillar is less than a net quantity of impurities in each of the plurality of first pillars. A net quantity of impurities in the fourth pillar is less than the net quantity of impurities in the third pillar.

### CROSS-REFERENCE TO RELATED APPLICATION

This application is based upon and claims the benefit of priority from the prior Japanese Patent Application No. 2011-206341, filed on Sep. 21, 2011; the entire contents of which are incorporated herein by reference.

### FIELD

Embodiments described herein relate generally to a power semiconductor device with a super junction structure in the drift layer.

### BACKGROUND

Power semiconductor devices normally have a vertical structure in which the current flows in the vertical direction, and require high withstand voltage as well as low electrical power consumption. Power semiconductor devices can include, for example, Metal Oxide Semiconductor Field Effect Transistors (MOSFETs), Insulated Gate Bipolar Transistors (IGBTs), Injection Enhanced Gate Transistors (IEGTs), and so on. For low electrical power consumption, it is necessary that the drift layer of power semiconductor devices have high impurity concentration and low resistance. On the other hand, for high withstand voltage, it is necessary that the drift layer of power semiconductor devices have low impurity concentration, so that depletion layers can easily spread. In other words, there is a tradeoff relationship between high withstand voltage and low electrical power consumption in power semiconductor devices. To improve this tradeoff relationship, a super junction structure is provided in the drift layers of power semiconductor devices.

A super junction structure is a structure in which a plurality of p-type pillars and n-type pillars that extend in the vertical direction are disposed alternately in the horizontal direction of the semiconductor element. By providing the same quantity of p-type impurities in p-type pillars as the quantity of n-type impurities in n-type pillars in the horizontal direction, there is a pseudo-undoped state in the super junction structure, so depletion layers can easily extend, and the withstand voltage of the power semiconductor device is improved. At the same time, when the power semiconductor device is in the on state, the n-type pillars with high concentration of n-type impurities form a current path in the drift layer, which promotes a low on resistance.

However, as a result of variation in the quantity of impurities injected in the manufacturing process, the withstand voltage at a termination region of super junction structures can be lower compared with the element region of the power semiconductor device. In order to improve the avalanche resistance of power semiconductor devices, it is desirable that the termination region of super junction structures have a structure with a higher withstand voltage than the element region.

### BRIEF DESCRIPTION OF THE DRAWINGS

FIG. 1 is a schematic cross-sectional view of the main parts of a power semiconductor device according to a first embodiment.

FIG. 2A is a schematic cross-sectional view of the main parts in a part of the manufacturing process of the power semiconductor device according to the first embodiment.

FIG. 2B is an enlarged view of the portion A in FIG. 2A.

FIG. 2C is a schematic cross-sectional view of the main parts in a part of the manufacturing process after that in FIG. 2A.

FIG. 3A is a schematic cross-sectional view of the main parts in a part of the manufacturing process of the power semiconductor device according to the first embodiment.

FIG. 3B is a schematic cross-sectional view of the main parts in a part of the manufacturing process after that in FIG. 3A.

FIG. 4 is a schematic cross-sectional view of the main parts in a part of the manufacturing process of a power semiconductor device according to a comparative example and corresponding to FIG. 2B.

FIG. 5 is a diagram showing the variations in the withstand voltage of the power semiconductor devices according to the first embodiment and the comparative example.

FIG. 6 is a schematic cross-sectional view of the main parts of a power semiconductor device according to a second embodiment.

FIG. 7A is a schematic cross-sectional view of the main parts in a part of the manufacturing process of the power semiconductor device according to the second embodiment.

FIG. 7B is an enlarged view of the portion F in FIG. 7A.

FIG. 8 is a schematic cross-sectional view of the main parts of a power semiconductor device according to a third embodiment.

FIG. 9A is a schematic cross-sectional view of the main parts in a part of the manufacturing process of the power semiconductor device according to the third embodiment.

FIG. 9B is an enlarged view of the portion G in FIG. 9A.

FIG. 10 is a schematic cross-sectional view of the main parts of a power semiconductor device according to a fourth embodiment.

FIG. 11A is a schematic cross-sectional view of the main parts in a part of the manufacturing process of the power semiconductor device according to the fourth embodiment.

FIG. 11B is an enlarged view of the portion H in FIG. 11A.

FIG. 12 is a schematic cross-sectional view of the main parts of a power semiconductor device according to a fifth embodiment.

FIG. 13 is a schematic cross-sectional view of the main parts in a part of the manufacturing process of the power semiconductor device according to the fifth embodiment and corresponding to FIG. 2B.

FIG. 14A is a drawing for schematically explaining the main parts of the first pillar region of the power semiconductor device according to the fifth embodiment.

FIG. 14B is a drawing for schematically explaining the main parts of the second pillar region of the power semiconductor device according to the fifth embodiment.

FIG. 15 is a schematic cross-sectional view of the main parts of a power semiconductor device according to a sixth embodiment.

FIG. 16 is a schematic cross-sectional view of the main parts in a part of the manufacturing process of the power semiconductor device according to the sixth embodiment and corresponding to FIG. 2B.

### DETAILED DESCRIPTION

A power semiconductor device includes a first semiconductor layer of a first conductivity type, a high resistance epitaxial layer, a second semiconductor layer of a second conductivity type, a third semiconductor layer of the first conductivity type, a gate electrode, a first electrode, and a second electrode. The first semiconductor layer has a first surface and a second surface on a side opposite to the first surface. The high resistance epitaxial layer is provided on the first surface of the first semiconductor layer and has a first pillar region and a second pillar region. The second semiconductor layer is selectively provided on a surface of the first pillar region. The third semiconductor layer is selectively provided on a surface of the second semiconductor layer. The gate electrode is provided on the first pillar region, the second semiconductor layer, and the third semiconductor layer, via a gate insulating film. The first electrode is electrically connected to the second surface of the first semiconductor layer. The second electrode is electrically connected to the second semiconductor layer and the third semiconductor layer, and insulated from the gate electrode via an inter-layer insulating film. The first pillar region includes a plurality of first pillars of the first conductivity type and a plurality of second pillars of the second conductivity type disposed alternately along a first direction parallel to the first surface of the first semiconductor layer. One of the plurality of second pillars of the second conductivity type is connected to the second semiconductor layer of the second conductivity type. The termination of the first pillar region along the first direction ends with either a first pillar or a second pillar. The second pillar region is adjacent to the first pillar region along the first direction via the termination. The second pillar region includes a third pillar having a conductivity type that is the opposite to the conductivity type of the pillar at the termination of the first pillar region, at an end on the first pillar region side along the first direction. The second pillar region further includes a fourth pillar of a conductivity type opposite to the conductivity type of the third pillar. The fourth pillar is disposed at another end opposite to the first pillar region side along the first direction. The plurality of first pillars, the plurality of second pillars, the third pillar, and the fourth pillar are each constituted from a plurality of steps of impurity diffused layers disposed along a second direction normal to the first surface of the first semiconductor layer. The impurity diffused layers of the plurality of first pillars, the plurality of second pillars, the third pillar, and the fourth pillar at a step of the plurality of steps of impurity diffused layers are disposed within a single layer parallel to the first surface of the first semiconductor layer. Within the single layer, a net quantity of impurities of the conductivity type of the third pillar in the impurity diffused layer of the third pillar is less than a net quantity of impurities of the first conductivity type in each impurity diffused layer of the plurality of first pillars and a net quantity of the impurities of the second conductivity type in each impurity diffused layer of the plurality of second pillars. Within the single layer, a net quantity of impurities of the conductivity type of the fourth pillar in the impurity diffused layer of the fourth pillar is less than the net quantity of impurities of the conductivity type of the third pillar in the impurity diffused layer of the third pillar.

Embodiments of the invention will now be described while referring to the drawings. The drawings used for explaining the embodiments are schematic for ease of explanation, the shape, dimensions, relationships of magnitude, and so on of each of the elements illustrated on the drawings are not necessarily the same on the drawings as in an actual embodiment, and they can be modified as appropriate within the range that the effect of the invention can be obtained. In the explanation of the embodiments, the first conductivity type is n-type and the second conductivity type is p-type, but it is also possible that these conductivity types are reversed. In the explanations the semiconductor is silicon as an example, but compound semiconductors such as SiC or GaN and so on can also be used. In the explanations a silicon oxide film is used as an insulating film, but other insulating materials such as a silicon nitride film, a silicon oxynitride film, alumina, and so on, can be used. When conductivity of the n-type is indicated by n⁺, n, n⁻, the n-type impurity concentration is lower in this order. Likewise with p-type, the p-type impurity concentration is lower in the order p⁺, p, p⁻. For both n-type impurities and p-type impurities, both gross impurity quantity and net impurity quantity are used. The gross quantity of n-type impurities means the gross quantity of n-type impurities in a semiconductor layer. The gross quantity of p-type impurities means the gross quantity of p-type impurities in a semiconductor layer. In contrast, the net quantity of n-type impurities means the gross quantity of n-type impurities less the gross quantity of p-type impurities (after impurity compensation) in a semiconductor layer. Likewise the net quantity of p-type impurities means the gross quantity of p-type impurities less the gross quantity of n-type impurities (after impurity compensation) in a semiconductor layer. When the result after deduction is a negative value, it means the net quantity of impurities of the opposite conductivity type. Each embodiment is explained using a MOSFET as an example, but an IGBT or an IEGT can also be used.

### First Embodiment

The following is an explanation of a power semiconductor device according to a first embodiment of the invention, using FIGS.

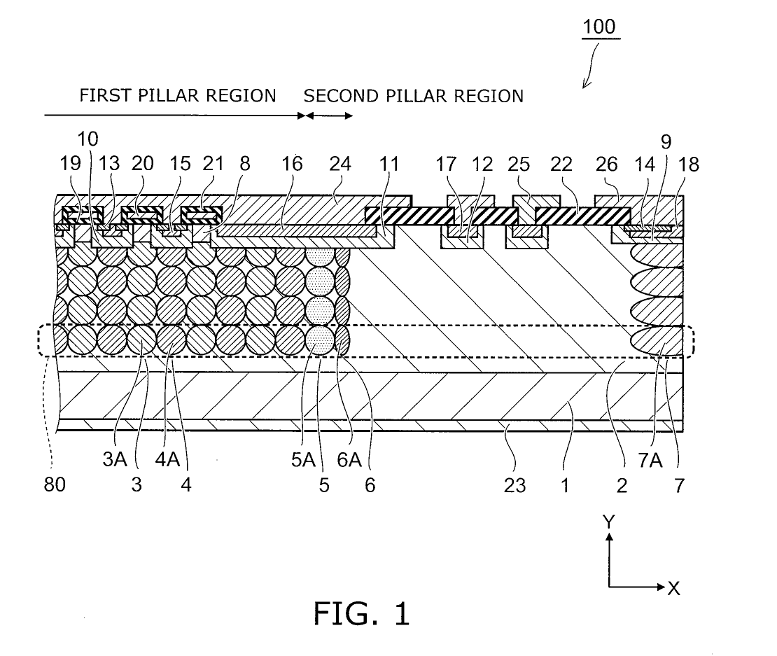

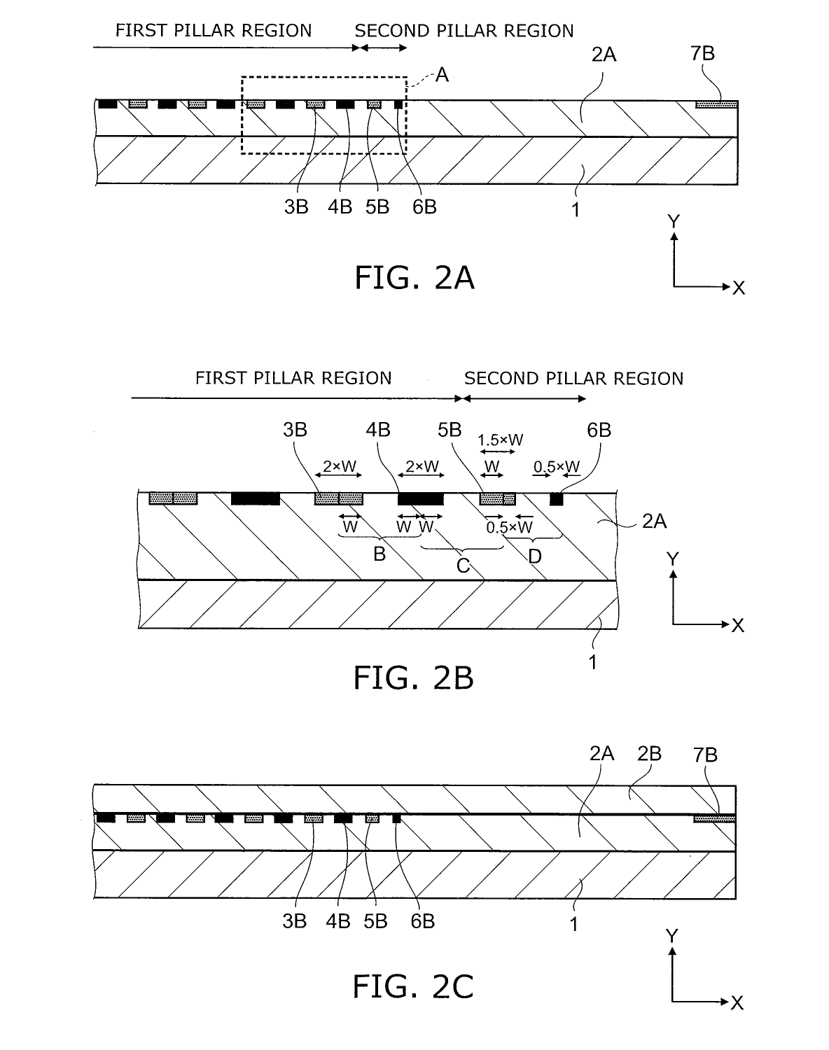

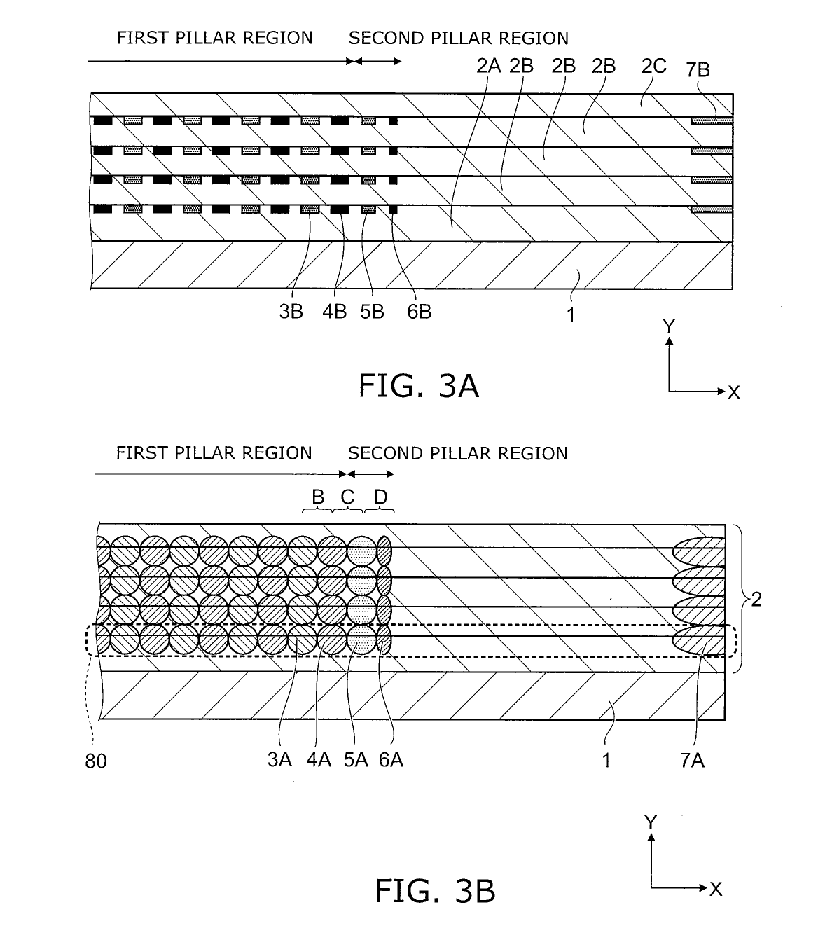

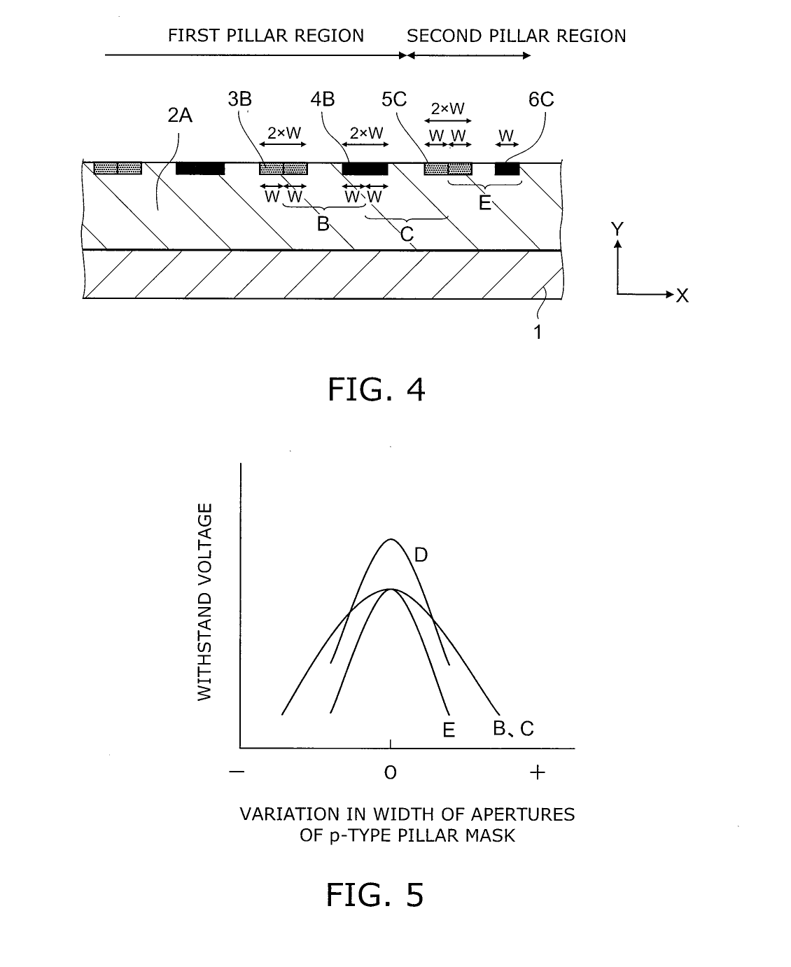

1 through 5. FIG. 1 is a schematic cross-sectional view of the main parts of the power semiconductor device according to the first embodiment. FIGS. 2A to 2C illustrate a part of the manufacturing process of the power semiconductor device according to the first embodiment, FIG. 2A is a schematic cross-sectional view of the main parts, FIG. 2B is an enlarged view of the portion A in FIG. 2A, and FIG. 2C is a schematic cross-sectional view of the main parts of the process after that in FIG. 2A. FIGS. 3A and 3B illustrate a part of the manufacturing process of the power semiconductor device according to the first embodiment, FIG. 3A is a schematic cross-sectional view of the main parts, and FIG. 3B is a schematic cross-sectional view of the main parts of the process after that in FIG. 3A. FIG. 4 illustrates a part of the manufacturing process of a power semiconductor device according to a comparative example, and is a schematic cross-sectional view of the main parts corresponding to FIG. 2B. FIG. 5 illustrates the variations in the withstand voltage of the power semiconductor devices according to the first embodiment and the comparative example.

As illustrated in FIG. 1, a power semiconductor device 100 according to this embodiment is a MOSFET, and includes an n⁺-type drain layer (first semiconductor layer of the first conductivity type) 1, an n⁻-type drift layer (high resistance epitaxial layer) 2, a p-type base layer (second semiconductor layer of the second conductivity type) 10, an n⁺-type source layer (third semiconductor layer of the first conductivity type) 13, a gate electrode 20, a drain electrode (first electrode) 23, and a source electrode (second electrode) 24. The n⁺-type drain layer 1 includes a first surface and a second surface on the opposite side thereof, and is made from silicon that includes a high concentration of n-type impurities. The n⁻-type drift layer 2 is provided on the first surface of the n⁺-type drain layer 1, and is, for example, a high resistance epitaxial layer 2 that is formed by epitaxial growth of undoped silicon. The high resistance epitaxial layer 2 includes a first pillar region and a second pillar region.

The first pillar region includes a plurality of n-type first pillars (first pillar of the first conductivity type) 3 and a plurality of p-type second pillars (second pillar of the second conductivity type) 4 disposed alternately along an X-direction (first direction) parallel to the first surface of the first semiconductor layer 1. As described later, the first pillars 3 and the second pillars 4 are made from a plurality of diffused layers 3A formed by diffusion of n-type impurities and a plurality of diffused layers 4A formed by diffusion of p-type impurities in the high resistance epitaxial layer 2, that extend through the high resistance epitaxial layer 2 from the surface of the high resistance epitaxial layer 2 on the side opposite to the n⁺-type drain layer 1 towards the n⁺-type drain layer 1. The termination along the X direction of the first pillar region terminates with either a first pillar 3 or a second pillar 4. In this embodiment, an example that terminates with a p-type second pillar is explained, but of course a structure that terminates with an n-type first pillar is also possible. Likewise for subsequent embodiments.

The second pillar region is adjacent to the first pillar region along the X direction via the termination fore-mentioned above. The second pillar region has an n-type third pillar (third pillar having the conductivity type that is the opposite to the conductivity type of the one pillar at the termination of the first pillar region) 5 which has the conductivity type that is the opposite to the conductivity type of the p-type second pillar 4 at the termination of the first pillar region, at one edge on the first pillar region side along the X direction, and a p-type (conductivity type that is the opposite to the third pillar) fourth pillar 6 at another edge on the side opposite to the first pillar region along the X direction. In other words, at the termination of the first pillar region, the p-type second pillar 4 and the n-type third pillar 5 are adjacent. Similar to the first pillar 3 and the second pillar 4, the third pillar 5 and the fourth pillar 6 are made from a plurality of diffused layers 5A formed by diffusion of n-type impurities and a plurality of diffused layers 6A formed by diffusion of p-type impurities in the high resistance epitaxial layer 2, extending through the high resistance epitaxial layer 2 from the surface of the high resistance epitaxial layer 2 on the side opposite to the n⁺-type drain layer 1 towards the n⁺-type drain layer 1, as described later. In this embodiment, the second pillar region only includes the third pillar 5 and the fourth pillar 6, and the third pillar 5 and the fourth pillar 6 are adjacent to each other.

The plurality of first pillars 3, the plurality of second pillars 4, the third pillar 5, and the fourth pillar 6 are each constituted from a plurality of steps of n-type or p-type impurity diffused layers 3A, 4A, 5A, and 6A which are disposed along the Y direction (second direction) normal to the first surface of the first semiconductor layer 1 and which are formed in the high resistance epitaxial layer 2. The impurity diffused layers 3A, 4A, 5A, and 6A of the plurality of first pillars 3, the plurality of second pillars 4, the third pillar 5, and the fourth pillar 6 which are at a same step are disposed within a single diffusion layer formation layer 80 that is parallel to the first surface of the first semiconductor layer 1. By superimposing a plurality of steps of this diffusion layer formation layer 80, the impurity diffused layers 3A of the first pillars 3, the impurity diffused layers 4A of the second pillars 4, the impurity diffused layers 5A of the third pillar 5, and the impurity diffused layers 6A of the fourth pillar 6 are stacked in the Y direction, and the first pillars 3, the second pillars 4, the third pillar 5, and the fourth pillar 6 are formed.

Within this single diffusion layer formation layer 80, a net quantity of n-type (the conductivity type of the third pillar 5) impurities in the impurity diffused layer 5A of the third pillar 5 is less than a net quantity of n-type (first conductivity type) impurities in each impurity diffused layer 3A of the plurality of first pillars 3 and a net quantity of p-type (second conductivity type) impurities in each impurity diffused layer 4A of the plurality of second pillars 4. Within this single diffusion layer formation layer 80, a net quantity of p-type (the conductivity type of the fourth pillar) impurities in the impurity diffused layer 6A of the fourth pillar 6 is less than the net quantity of n-type (the conductivity type of the third pillar 5) impurities in the impurity diffused layer 5A of the third pillar 5. Here, by making a gross quantity of n-type impurities in the impurity diffused layer 5A of the third pillar 5 to be less than a gross quantity of n-type impurities in the n-type impurity diffused layers 3A of the first pillars 3 and a gross quantity of p-type impurities in the p-type impurity diffused layer 4A of the second pillars 4, the net quantity of n-type impurities in the n-type impurity diffused layer 5A of the third pillar 5 is made to be less than the net quantity of n-type impurities in the n-type impurity diffused layers 3A of the first pillars 3 and the net quantity of p-type impurities in the p-type impurity diffused layers 4A of the second pillars 4. Also, by making a gross quantity of p-type impurities in the p-type impurity diffused layer 6A of the fourth pillar 6 to be less than the gross quantity of n-type impurities in the n-type impurity diffused layer 5A of the third pillar 5, the net quantity of p-type (the conductivity type of the fourth pillar) impurities in the p-type impurity diffused layer 6A of the fourth pillar 6 is made to be less than the net quantity of n-type impurities in the n-type impurity diffused layer 5A of the third pillar 5.

The p-type base layer (second semiconductor layer of the second conductivity type) 10 is selectively provided on the surface of the first pillar region. The p-type base layer 10 is provided on the p-type second pillar 4, and is electrically connected to the p-type second pillar 4. An n-type semiconductor layer 8 is provided on the n-type first pillar 3 between adjacent p-type base layers 10 in the X direction, and adjacent to these p-type base layers 10, and is electrically connected to the n-type first pillar 3.

A p-type carrier removal layer 11 is provided on the surface of the termination of the first pillar region and the surface of the second pillar region, and is electrically connected to the p-type second pillar 4 and the p-type fourth pillar 6. Two p-type guard ring layers 12 are provided on the surface of the high resistance epitaxial layer 2 on the side opposite to the n⁺-type drain layer 1 separated from the p-type carrier removal layer 11, and separated from each other with the high resistance epitaxial layer 2 disposed between the two p-type guarding layers 12. An n-type channel stopper layer 7 is provided extending through the high resistance epitaxial layer 2 from the surface of the high resistance epitaxial layer 2 on the side opposite to the n⁺-type drain layer 1 towards the n⁺-type drain layer 1. The high resistance epitaxial layer 2 is die cut at the n-type channel stopper layer 7. An n-type semiconductor layer 9 is provided on the top end of the n-type channel stopper layer 7. A p⁺-type semiconductor layer 18 is provided on the surface of the n-type semiconductor layer 9, and an n⁺-type semiconductor layer 14 is provided on the surface of the p⁺-type semiconductor layer 18.

The n⁺-type source layer (third semiconductor layer of the first conductivity type) 13 is selectively provided on the surface of the p-type base layer 10. The gate electrode 20 is provided on the n-type semiconductor layer 8, the p-type base layer 10, and the n⁺-type source layer 13 via a gate insulating film 19 . The drain electrode 23 is electrically connected to the second surface of the n⁺-type drain layer 1. The source electrode 24 is electrically connected to the p-type base layer 10 and the n⁺-type source layer 13, and is insulated from the gate electrode 20 via a first inter-layer insulating film 21. Also, the source electrode 24 is electrically connected to the p-type carrier removal layer 11. The source electrode 24 is electrically connected to the p-type base layer 10 and the p-type carrier removal layer 11 with low resistance, via p⁺-type contact layers 15 and 16. For example, a silicon oxide film is used for the gate insulating film 19 and the first inter-layer insulating film 21.

A second inter-layer insulating film 22 is provided on one end of the p-type carrier removal layer on the side opposite to the gate electrode 20, on the high resistance epitaxial layer 2, on the two p-type guard ring layers 12, and on the n-type semiconductor layer 9. Two field plate electrodes 25 are electrically connected to the two p-type guard ring layers 12 with low resistance at apertures in the second inter-layer insulating film 22 via a p⁺-type contact layer 17. A channel stopper electrode 26 is electrically connected to the n⁺-type semiconductor layer 14 at another aperture in the second inter-layer insulating film. A silicon oxide film, for example, is used for the second inter-layer insulating film.

As explained above, the power semiconductor device 100 according to this embodiment includes a super junction structure having the first through fourth pillars formed in the first pillar region and the second pillar region in the high resistance epitaxial layer (n⁻-type drift layer) 2. Next, the method of manufacturing the super junction structure provided in the power semiconductor device 100 according to this embodiment is explained using FIGS. 2A to 2C, FIGS. 3A, and 3B. FIGS. 2A, 2C, 3A, and 3B are schematic cross-sectional views of the main parts illustrating an outline of a process for manufacturing the high resistance epitaxial layer 2. FIG. 2B illustrates an enlargement of the portion A in FIG. 2A.

As illustrated in FIG. 2A, an undoped silicon layer is epitaxially grown on the first surface of the n⁺-type drain layer 1, and a first layer 2A of the high resistance epitaxial layer 2 is formed. In the regions of the surface of the first layer 2A of the high resistance epitaxial layer where the first pillar region and the second pillar region will be formed, n-type impurities, for example phosphorous (P), are ion implanted at predetermined gaps in the X direction, using a resist mask, which is not illustrated on the drawings, for injecting n-type impurities and that has apertures of predetermined widths for the first pillars 3 and the third pillars 5. In this way, a plurality of n-type impurity injection layers 3B for the first pillars 3 is formed at predetermined gaps in the X direction in the first pillar region. An n-type impurity injection layer 5B for the third pillar 5 is formed at an end on the first region side of the second pillar region at a predetermined gap in the X direction from the n-type impurity injection layer 3B for the first pillars 3 formed at the termination of the first region.

Likewise, p-type impurities, for example boron (B), are ion implanted using a resist mask, which is not illustrated on the drawings, for injection of p-type impurities having apertures of predetermined widths for the second pillar 4 and the fourth pillar 6, between adjacent n-type impurity injection layers 3B, between the n-type impurity injection layer 3B and the n-type impurity injection layer 5B, and in a position adjacent to the n-type impurity injection layer 5B, at a predetermined gap from the n-type impurity injection layer 3B and the n-type impurity injection layer 5B in the X direction. In this way, a plurality of p-type impurity injection layers 4B for the second pillar 4 is formed between the n-type impurity injection layers 3B for the n-type first pillars 3, and between the n-type impurity injection layer 3B for the n-type first pillar 3 and the n-type impurity injection layer 5B for the n-type third pillar 5, in each case at a predetermined gap from the n-type impurity injection layer 3B of the n-type first pillar 3. A p-type impurity injection layer 6B for the fourth pillar 6 is formed at another end of the second pillar region on the side opposite to the first pillar region in the X direction, and separated from the n-type impurity injection layer 5B for the n-type third pillar 5. In this embodiment, in the second pillar region, no other pillar is formed between the n-type third pillar 5 and the p-type fourth pillar 6, so one each of the n-type impurity injection layer 5B for the third pillar 5 and the p-type impurity injection layer 6B for the fourth pillar 6 are formed.

Next, as illustrated in FIG. 2C, again an undoped silicon layer is epitaxially grown on the surface of the high resistance epitaxial layer on which each of the impurity injection layers 3B, 4B, 5B, and 6B is formed, and a second layer 2B of the high resistance epitaxial layer 2 is formed. Here again ion implantation of n-type impurities and ion implantation of p-type impurities are carried out using a resist mask for injection of n-type impurities and a resist mask for injection of p-type impurities, which are not illustrated on the drawings, and the n-type and the p-type impurity injection layers 3B, 4B, 5B, and 6B are formed. Thereafter, this formation of the high resistance epitaxial layer 2B by epitaxial growth of the undoped silicon layer and formation of the n-type and the p-type impurity injection layers 3B, 4B, 5B, and 6B are repeated the necessary number of times, and thereafter a final layer 2C of the high resistance epitaxial layer 2 is formed.

As a result of this process, as illustrated in FIG. 3A, a structure in which a plurality of steps of the n-type impurity injection layers 3B for the first pillars, a plurality of steps of the p-type impurity injection layers 4B for the second pillars, a plurality of steps of the n-type impurity injection layer 5B for the third pillar, and a plurality of steps of the p-type impurity injection layer 6B for the fourth pillar are disposed in the high resistance epitaxial layer 2 and separated from each other along the Y direction. This embodiment has a 4-step structure. Here, although omitted from the explanation, an n-type impurity injection layer 7B for the channel stopper layer 7 is formed at the same time as the n-type impurity injection layer 3B and the n-type impurity injection layer 5B, at a portion for die cutting the high resistance epitaxial layer 2.

A plurality of steps of the n-type impurity injection layer 7B is disposed in the high resistance epitaxial layer 2 separated from each other in the Y direction.

Thereafter, the impurities in each of the n-type impurity injection layers 3B, 5B, and 7B, and the p-type impurity injection layers 4B and 6B are diffused through the high resistance epitaxial layer 2 by annealing, and the impurity diffused layers 3A, 4A, 5A, 6A, and 7A are formed corresponding to the impurity injection layers 3B, 4B, 5B, 6B, and 7B respectively, as illustrated in FIG. 3B. The plurality of steps of the n-type impurity diffused layers 3A join along the Y direction, to form a plurality of the n-type first pillars.

Likewise, the plurality of steps of the p-type impurity diffused layers 4A join to form a plurality of the p-type second pillars. Likewise, the plurality of steps of the n-type impurity diffused layers 5A join to form the n-type third pillar. Likewise, the plurality of steps of the p-type impurity diffused layers 6A join to form the p-type fourth pillar. Likewise, the n-type impurity diffused layers 7A join to form the n-type channel stopper layer 7. Each of the pillars of the first through fourth pillars 3, 4, 5, and 6 has a structure in which each of the impurity diffused layers 3A, 4A, 5A, and 6A is joined in the Y direction, and extends through the high resistance epitaxial layer 2 from the surface of the high resistance epitaxial layer 2 on the side opposite to the n⁺-type drain layer 1 towards the n⁺-type drain layer side.

In each step (for example, the first step), a single layer (diffusion layer formation layer, as described previously) 80 is formed disposed parallel to the first surface of the n⁺-type drain layer 1 for each of the impurity diffused layers 3A, 4A, 5A, 6A, and 7A of each pillar. In other words, the diffusion layer formation layer 80 of each step includes in the first pillar region the plurality of n-type impurity diffused layers 3A of the n-type first pillars 3 and the plurality of p-type impurity diffused layers 4A of the p-type second pillars 4 disposed alternately along the X direction, includes in the second pillar region the n-type impurity diffused layer 5A of the n-type third pillar 5 at one end on the first region side, and includes in the second pillar region the p-type impurity diffused layer 6A of the p-type fourth pillar 6 at another end on the side opposite to the first region side in the X direction. In the X direction, the n-type impurity diffused layers 3A of the first pillars 3 and the p-type impurity diffused layers 4A of the second pillars 4 are adjacent, and the n-type impurity diffused layer 5A of the third pillar 5 and the p-type impurity diffused layer 6A of the fourth pillar are adjacent. Also, at the boundary between the first pillar region and the second pillar region (at the termination of the first pillar region in the X direction), the p-type impurity diffused layer 4A of the second pillar 4 and the n-type impurity diffused layer 5A of the third pillar 5 are adjacent.

At adjoining portions of each of these pillars in the X direction (portions where adjacent pillars adjoin), the impurities in the impurity diffused layers overlap causing impurity compensation (hereafter the regions where the impurity diffused layers overlap causing impurity compensation are referred to as “impurity compensation regions”). In an impurity compensation region, the n-type impurities in an n-type impurity diffused layer and the p-type impurities in a p-type impurity diffused layer are mixed, and as a result of impurity compensation, the net quantity of impurities in the impurity diffused layers is determined. For example, the n-type impurity diffused layers 3A of the n-type first pillars 3 and the p-type impurity diffused layers 4A of the p-type second pillars have an impurity compensation region in an adjacent portion where they partially overlap, within the diffusion layer formation layer 80. Within this impurity compensation region, where the concentration of n-type impurities and the concentration of p-type impurities are equal, p-n junctions are formed. As a result, the gross quantity of n-type impurities in the n-type impurity diffused layer minus the quantity of p-type impurities in the impurity compensation region (the quantity of p-type impurities in the p-type diffusion layer in the impurity compensation region) is equal to the net quantity of n-type impurities in the n-type impurity diffused layer 3A. Even if the gross quantity of n-type impurities is fixed, the quantity of compensated impurities increases with increasing of the impurity compensation region, so the net quantity of n-type impurities is reduced. In other words, as impurity diffusion progresses, the overlap of n-type impurity diffused layers and p-type impurity diffused layers in the X direction becomes greater, so the net quantity of each type of impurity is reduced.

Thereafter, using existing semiconductor processes for manufacturing MOSFETs, the p-type base layer 10, the p-type carrier removal layer 11, the p-type guard ring layers 12, the n-type semiconductor layers 8 and 9, the n⁺-type source layer 13, the p⁺-type contact layers 15, 16, and 17, the p⁺-type semiconductor layer 18, the n⁺-type semiconductor layer 14, the gate insulating film 19, the gate electrode 20, the first inter-layer insulating film 21, the second inter-layer insulating film 22, the first electrode 23, the second electrode 24, the field plate electrodes 25, the channel stopper electrode 26, and so on, are formed, and the power semiconductor device 100 illustrated in FIG. 1 is manufactured.

Here, in order that the first through fourth pillars formed in the first pillar region and the second pillar region function as a super junction structure, the gross quantity of impurities in each pillar is set as follows. In the first pillar region and the second pillar region, depletion layers can easily spread from their adjoining portions into the adjacent n-type pillars and the p-type pillars, so it is necessary to set the gross quantities of impurities of both pillars to be equal. In other words, as illustrated in FIG. 3B, in the first pillar region, in a portion B where the first pillar 3 and the second pillar 4 are in opposition, the gross quantity of n-type impurities and the gross quantity of p-type impurities are set to be equal. Also, at the boundary between the first pillar region and the second pillar region, in a portion C where the second pillar 4 and the third pillar 5 are in opposition, the gross quantity of n-type impurities and the gross quantity of p-type impurities are set to be equal. In addition, in the second pillar region, in a portion D where the third pillar 5 and the fourth pillar 6 are in opposition, the gross quantity of n-type impurities and the gross quantity of p-type impurities are set to be equal.

The gross quantity of impurities in each pillar is determined by each gross quantity of impurities in each of the impurity diffused layer 3A, 4A, 5A, and 6A in the diffusion layer formation layer 80. The gross quantity of impurities in each of the impurity diffused layers 3A, 4A, 5A, and 6A is determined by the gross quantity of n-type and p-type impurities in each of the corresponding impurity injection layers 3B, 4B, 5B, and 6B as stated previously. In other words, it is determined by the width in the X direction of each of the impurity injection layers 3B, 4B, 5B, and 6B, and this is determined by the width of the apertures in the resist mask used for ion implantation. In this embodiment, the widths in the X direction of each of the impurity injection layers 3B, 4B, 5B, and 6B are set as indicated below.

As illustrated in FIG. 2B, the n-type impurity injection layers 3B of the first pillars 3 formed in the first pillar region are formed so that the width in the X direction is 2×W. Here, W is an arbitrary width. Likewise, the p-type impurity injection layers 4B of the second pillars 4 formed in the first pillar region are formed so that the width in the X direction is 2×W. In this way, in the diffusion layer formation layer 80 of each step, in the first pillar region, in the portion B where the first pillar 3 and the second pillar 4 are in opposition, the gross quantity of n-type impurities in the second pillar side half of the impurity diffused layer 3A of the first pillar 3 and the gross quantity of p-type impurities in the first pillar side half of the impurity diffused layer 4A of the second pillar 4 are equal.

The n-type impurity injection layer 5B formed in the second pillar region is formed so that the width in the X direction is 1.5×W. The p-type impurity injection layer 6B formed in the second pillar region is formed so that the width in the X direction is 0.5×W. In this way, in the diffusion layer formation layer 80 of each step, at the boundary between the first pillar region and the second pillar region, in other words in the portion C where the second pillar 4 and the third pillar 5 are in opposition, the gross quantity of p-type impurities in the third pillar 5 side half of the impurity diffused layer 4A of the second pillar 4 and the gross quantity of n-type impurities in the second pillar 4 side portion (portion corresponding to the width W) of the impurity diffused layer 5A of the third pillar 5 are equal. Also, in the second region, in the portion D where the third pillar 5 and the fourth pillar 6 are in opposition, the gross quantity of n-type impurities in the remaining portion (portion corresponding to 0.5×W) on the fourth pillar 6 side of the impurity diffused layer 5A of the third pillar 5 and the gross quantity of p-type impurities in the whole impurity diffused layer 6A of the fourth pillar 6 are equal.

As a result of the above, the gross quantity of n-type impurities and the gross quantity of p-type impurities in the first pillar region and the second pillar region as a whole are equal in the high resistance epitaxial layer 2, so a pseudo-undoped layer is formed. In this embodiment, it is considered that the overlap of impurity diffused layers in the X direction (impurity compensation regions) can be ignored, so it is considered that the gross quantity of n-type and p-type impurities in the impurity diffused layers of each pillar is approximately equal to the respective net quantity of n-type and p-type impurities. Hereafter the same is considered up to the fourth embodiment.

The MOSFET 100 according to this embodiment includes the high resistance epitaxial layer 2 having a super junction structure that includes the first pillar region and the second pillar region as a drift layer. When the MOSFET 100 is in the on state, current flows from the drain electrode 23 to the source electrode 24 via the n⁺-type drain layer 1, the n-type first pillar 3, the n-type semiconductor layer 8, the p-type base layer 10, and the n⁺-type source layer 13. The n-type impurity concentration of the n-type pillars which form the current path can be set to be high, so the on resistance of the MOSFET 100 is low. Also, when in the off state, depletion layers can easily spread from the p-n junctions of the n-type first pillar 3 and the p-type second pillar 4, so the withstand voltage of the MOSFET 100 is high.

As described above, in the manufacturing process of forming the first pillar region and the second pillar region, the gross quantity of n-type impurities in each n-type impurity diffused layer and the gross quantity of p-type impurities in each p-type impurity diffused layer are determined by the width of each n-type impurity injection layer and each p-type impurity injection layer respectively. In other words, the gross quantity of impurities in each impurity injection layer is determined by the width of the apertures of the mask used for ion implantation of each of the impurities. In order to maintain a high withstand voltage while maintaining a low MOSFET 100 on resistance, it is necessary to precisely control the gross quantity of n-type impurities and the gross quantity of p-type impurities in adjacent pillars in the first and second pillar regions. In a super junction structure, when the gross quantity of n-type impurities and the gross quantity of p-type impurities in adjacent pillars are equal, the withstand voltage is the highest. As one of the gross quantity of n-type impurities and the gross quantity of p-type impurities in adjacent pillars becomes larger, the withstand voltage of the super junction structure reduces sharply. Therefore, in the process of manufacturing the first pillar region and the second pillar region, variation in the widths of the apertures of the mask used for ion implantation is a problem. The MOSFET 100 according to this embodiment has a structure that is capable of suppressing the reduction in withstand voltage due to variation in the aperture widths of the mask when forming the pillars, and this characteristic is explained below by comparison with a comparative example.

Using FIG. 4, the characteristics of the process of manufacturing the first pillar region and the second pillar region according to the comparative example are explained. FIG. 4 illustrates the process of forming each impurity injection layer of the first through fourth pillars in the first pillar region and the second pillar region according to the comparative example, and this drawing corresponds to FIG. 2B in the manufacturing process of forming the first pillar region and the second pillar region in this embodiment. Using FIG. 4, the points of difference in the structure of the first pillar region and the second pillar region according to the comparative example from the first pillar region and the second pillar region according to this embodiment are explained.

As illustrated in FIG. 4, in the comparative example, the n-type impurity injection layers 3B that form the n-type impurity diffused layers 3A of the n-type first pillars 3 formed in the first pillar region are formed with a width in the X direction of 2×W, likewise the p-type impurity injection layers 4B that form the p-type impurity diffused layers 4A of the p-type second pillars 4 formed in the first pillar region are formed with a width in the X direction of 2×W. As a result, in each step of the diffusion layer formation layer 80, in the first pillar region, in the portion B where the first pillar 3 and the second pillar 4 are in opposition, the gross quantity of n-type impurities in the second pillar side half of the impurity diffused layer 3A of the first pillar 3 and the gross quantity of p-type impurities in the first pillar side half of the impurity diffused layer 4A of the second pillar 4 are equal. This point is the same as the first pillar and the second pillar of the MOSFET 100 according to this embodiment.

The n-type impurity injection layer 5C that forms the n-type impurity diffused layer 5A of the n-type third pillar 5 formed in the second pillar region is formed with a width in the X direction of 2×W. The p-type impurity injection layer 6C that forms the p-type impurity diffused layer 6A of the p-type fourth pillar 6 formed in the second pillar region is formed with a width in the X direction of W. In this way, in each step of the diffusion layer formation layer 80, at the boundary between the first pillar region and the second pillar region, in other words at the portion C where the second pillar 4 and the third pillar 5 are in opposition, the gross quantity of p-type impurities in the third pillar 5 side half of the impurity diffused layer 4A of the second pillar 4 and the gross quantity of n-type impurities in the second pillar 4 side half (the portion corresponding to W) of the impurity diffused layer 5A of the third pillar 5 are equal. Also, in the second region, at the portion

E where the third pillar 5 and the fourth pillar 6 are in opposition, the gross quantity of n-type impurities in the fourth pillar 6 side half (the portion corresponding to W) of the impurity diffused layer 5A of the third pillar 5 and the gross quantity of p-type impurities in the whole impurity diffused layer 6A of the fourth pillar 6 are equal. The width in the X direction of the n-type impurity injection layer 5C of the n-type third pillar 5 of the second pillar region and the width in the X direction of the p-type impurity injection layer 6C of the p-type fourth pillar 6 are different from the width of the impurity injection layers 5B and 6B of the third pillar 5 and the fourth pillar 6 according to this embodiment. Apart from this point, there are no differences between the first and second pillar regions according to the comparative example and the first and second pillar regions according to this embodiment.

In the first pillar region and the second pillar region according to the comparative example also, in each of the portion

B where the first pillar 3 and the second pillar 4 are in opposition, the portion C where the second pillar 4 and the third pillar 5 are in opposition, and the portion E where the third pillar and the fourth pillar are in opposition, the gross quantity of impurities in each of the impurity diffused layers is set so that the gross quantity of n-type impurities and the gross quantity of p-type impurities are equal. However, as stated above, the width in the X direction of the n-type impurity injection layer 5C of the third pillar 5 and the width in the X direction of the p-type impurity injection layer 6C of the fourth pillar 6 according to the comparative example are wider than those of the third pillar 5 and the fourth pillar 6 according to this embodiment, respectively.

In other words, in the comparative example, the width in the X direction of the n-type impurity injection layer 5C of the third pillar 5 is set to be the same width (2×W) as the width in the X direction of the impurity injection layer 3B of the first pillar 3 and the impurity injection layer 4B of the second pillar 4. In other words, the gross quantity of the n-type impurities in the n-type impurity diffused layer 5A of the third pillar 5 is set to be the same quantity as the gross quantity of n-type impurities in the n-type impurity diffused layer 3A of the first pillar 3 and the gross quantity of p-type impurities in the p-type impurity diffused layer 4A of the second pillar 4. Also, the width of the p-type impurity injection layer 6C of the fourth pillar 6 is set to be half (W) the width in the X direction of the impurity injection layer 3B of the first pillar 3 and the impurity injection layer 4B of the second pillar 4. In other words, the gross quantity of p-type impurities in the p-type impurity diffused layer 6A of the fourth pillar 6 is set to be half the gross quantity of n-type impurities in the n-type impurity diffused layer 3A of the first pillar 3 and the gross quantity of p-type impurities in the p-type impurity diffused layer 4A of the second pillar 4.

In contrast, in this embodiment, the width in the X direction of the n-type impurity injection layer 5B of the third pillar 5 is 1.5×W, so it is set to be ¾ times the width in the X direction of the n-type impurity injection layer 3B of the first pillar 3 and the p-type impurity injection layer 4B of the second pillar 4. In other words, the gross quantity of the n-type impurities in the n-type impurity diffused layer 5A of the third pillar is set to be ¾ times the gross quantity of n-type impurities in the n-type impurity diffused layer 3A of the first pillar 3 and the gross quantity of p-type impurities in the p-type impurity diffused layer 4A of the second pillar 4. Also, the width of the p-type impurity injection layer 6B of the fourth pillar 6 is set to be ¼ times the width in the X direction of the n-type impurity injection layer 3B of the first pillar 3 and the p-type impurity injection layer 4B of the second pillar 4. In other words, the gross quantity of p-type impurities in the p-type impurity diffused layer 6A of the fourth pillar 6 is set to be ¼ times the gross quantity of n-type impurities in the n-type impurity diffused layer 3A of the first pillar 3 and the gross quantity of p-type impurities in the p-type impurity diffused layer 4A of the second pillar 4.

In other words, in this embodiment, the gross quantity of the n-type impurities in the n-type impurity diffused layer 5A of the third pillar is set to be less than the gross quantity of n-type impurities in the n-type impurity diffused layer 3A of the first pillar 3 and the gross quantity of p-type impurities in the p-type impurity diffused layer 4A of the second pillar 4. Also, the gross quantity of p-type impurities in the p-type impurity diffused layer 6A of the fourth pillar 6 is set to be less than the gross quantity of n-type impurities in the n-type impurity diffused layer 5A of the third pillar 5. In this embodiment, as an example, the gross quantity of p-type impurities in the p-type impurity diffused layer 6A of the fourth pillar was set to be ¼ times the gross quantity of n-type impurities in the n-type impurity diffused layer 3A of the first pillar 3 and the gross quantity of p-type impurities in the p-type impurity diffused layer 4A of the second pillar 4, but it may be set to be less than half.

Next, FIG. 5 illustrates the withstand voltage of a MOSFET having a drift layer with a super junction structure constituted from the first pillar region and the second pillar region according to the comparative example. The p-type impurity injection layer 4B of the second pillar 4 and the p-type impurity injection layer 6C of the fourth pillar 6 were formed by ion implantation using a mask for forming p-type pillars. As shown in FIG. 5, the withstand voltage of the MOSFET varies greatly depending on variation in the width of the apertures of the mask for forming the p-type pillars. Here, variation in the width of the apertures of the mask for forming the p-type pillars is variation in the finish of the width of the apertures of the resist mask. This is produced by the light exposure conditions and the variation in the width of the apertures of the photomask used in lithography.

When the variation in the width of the apertures of the mask for forming the p-type pillars is zero, the width in the X direction of the p-type impurity injection layer is formed in accordance with the design, so the gross quantity of n-type impurities and the gross quantity of p-type impurities between the opposing n-type pillars and p-type pillars are equal. At this time, the portion B where the first pillar and the second pillar are in opposition, the portion C where the second pillar and the third pillar are in opposition, and the portion E where the third pillar and the fourth pillar are in opposition each have the maximum withstand voltage. When there is variation in the width of the apertures of the mask for forming the p-type pillars, the withstand voltage sharply reduces. Compared with the portion B where the first pillar 3 and the second pillar 4 are in opposition and the portion C where the second pillar and the third pillar are in opposition, at the portion E where the third pillar 5 and the fourth pillar 6 are in opposition the withstand voltage sharply reduces with variation in the mask for forming the p-type pillars.

The reason for this is as follows. The fourth pillar 6 is in balance with the gross quantity of impurities in the third pillar 5 and is easily depleted, so it is set to be half the gross quantity of n-type impurities in the n-type impurity diffused layer 3A of the first pillar 3 and the gross quantity of the p-type impurities in the p-type impurity diffused layer 4A of the second pillar. The effect on the withstand voltage of the variation in the width of the mask for forming the p-type pillars increases the smaller the gross quantity of impurities in the pillar. Therefore, at the portion E where the third pillar 5 and the fourth pillar 6 are in opposition, the withstand voltage is reduced greatly when there is variation in the width of the mask for forming the p-type pillars, more than at the portion B where the first pillar 3 and the second pillar 4 are in opposition and the portion C where the second pillar 4 and the third pillar 5 are in opposition. Variation in the width of the mask for forming the p-type pillars is certain to exist during manufacture, so in the MOSFET having the first pillar region and the second pillar region according to the comparative example, breakdown occurs first in the second pillar region before the first pillar region. The second pillar region is the MOSFET termination region, and its area is smaller than that of the element region of the first pillar region, so the avalanche resistance of the MOSFET according to the comparative example is low.

In contrast, in the MOSFET 100 according to this embodiment, equality of the gross quantity of n-type impurities and the p-type impurities in the portion D where the third pillar 5 and the fourth pillar 6 are in opposition is maintained, and the gross quantity of n-type impurities in the n-type impurity diffused layer 5A of the third pillar 5 and the gross quantity of the p-type impurities in the p-type impurity diffused layer 6A of the fourth pillar 6 are set to be less than the gross quantity of impurities in the first pillar 3 and the second pillar 4 respectively in the first pillar region. Therefore, as illustrated in FIG. 5, in this embodiment, compared with the comparative example, depletion layers can spread more easily in the portion D where the third pillar 5 and the fourth pillar 6 are in opposition in the second pillar region compared with the portion B where the first pillar 3 and the second pillar 4 are in opposition in the first pillar region, so the withstand voltage is further improved. As illustrated in FIG. 5, if the variation in the width of the apertures of the mask for forming the p-type pillars is restricted to be within the area where the withstand voltage of the portion D where the third pillar 5 and the fourth pillar 6 are in opposition is higher than the withstand voltage of the portion B where the first pillar 3 and the second pillar 4 are in opposition, then breakdown will always occur first in the first pillar region before the second pillar region. Therefore the avalanche resistance of the MOSFET 100 according to this embodiment is higher than that of the comparative example. Therefore, the MOSFET 100 according to this embodiment suppresses the reduction in withstand voltage in the termination region due to manufacturing variation in the super junction structure.

In this embodiment, as an example the gross quantity of n-type impurities in the n-type impurity diffused layer 5A of the third pillar 5 was set to be ¾ times the gross quantity of n-type impurities in the n-type impurity diffused layer 3A of the first pillar 3 and the gross quantity of p-type impurities in the p-type impurity diffused layer 4A of the second pillar 4. Also, the gross quantity of p-type impurities in the p-type impurity diffused layer 6A of the fourth pillar 6 was set to be ¼ times the gross quantity of n-type impurities in the n-type impurity diffused layer 3A of the first pillar 3 and the gross quantity of p-type impurities in the p-type impurity diffused layer 4A of the second pillar 4. The above effect of this embodiment is not limited to this, and the gross quantity of n-type impurities in the n-type impurity diffused layer 5A of the third pillar 5 may be set to be less than the gross quantity of n-type impurities in the n-type impurity diffused layer 3A of the first pillar 3 and the gross quantity of p-type impurities in the p-type impurity diffused layer 4A of the second pillar 4. Also, the gross quantity of p-type impurities in the p-type impurity diffused layer 6A of the fourth pillar 6 may be set to be less than the gross quantity of n-type impurities in the n-type impurity diffused layer 5A of the third pillar 5. Preferably the gross quantity of p-type impurities in the p-type impurity diffused layer 6A of the fourth pillar 6 is set to be not more than half the gross quantity of n-type impurities in the n-type impurity diffused layer 3A of the first pillar 3 and the gross quantity of p-type impurities in the p-type impurity diffused layer 4A of the second pillar 4.

In this embodiment, an example was explained in which the first pillar region terminated with the p-type second pillar 4.

However, when the first pillar region terminates with the n-type first pillar 3, an effect that is the same as the effect of the embodiment explained above can be obtained. In this case, the conductivity type of the n-type third pillar in the second pillar region is changed to the p-type, and the conductivity type of the p-type fourth pillar is changed to the n-type. Likewise for subsequent embodiments.

### Second Embodiment

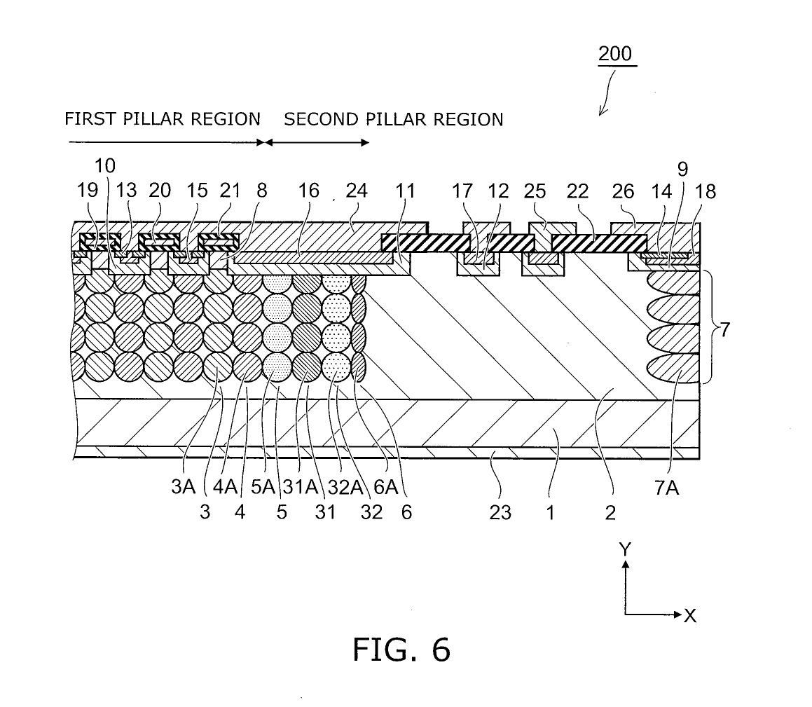

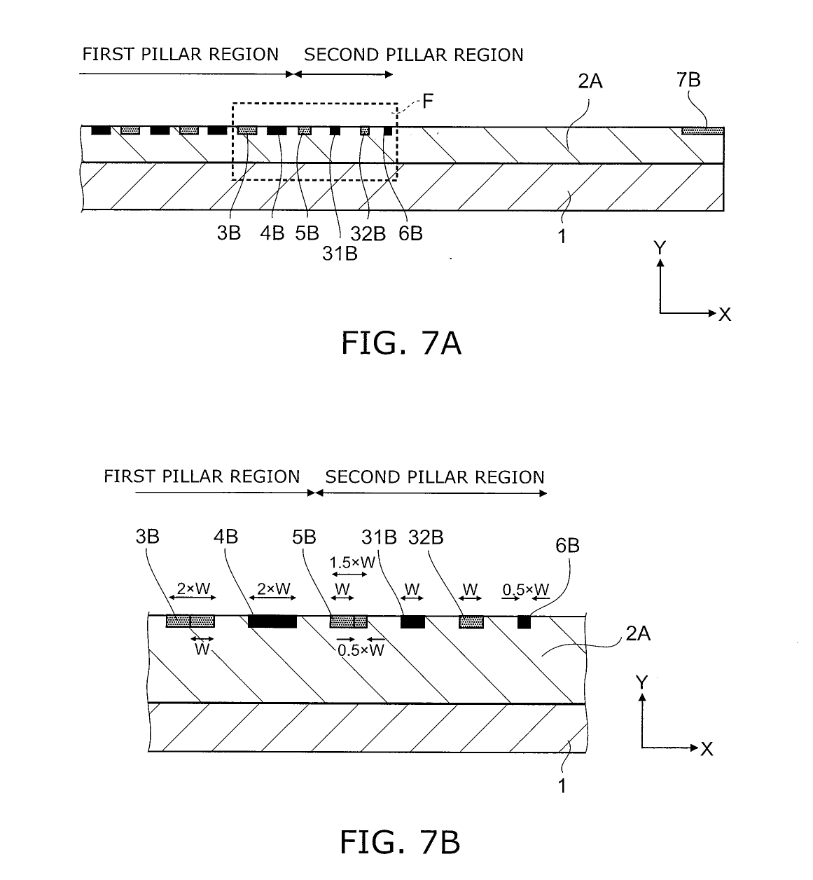

The following is an explanation of a power semiconductor device 200 according to a second embodiment using FIGS. 6 and 7. FIG. 6 is a schematic cross-sectional view of the main parts of the power semiconductor device according to the second embodiment. FIGS. 7A and 7B illustrate a part of the manufacturing process of the power semiconductor device according to the second embodiment, FIG. 7A is a schematic cross-sectional view of the main parts, and FIG. 7B is an enlarged view of the portion F in FIG. 7A. Portions having the same constitution as the constitution explained in the first embodiment use the same reference number or symbol, and their explanation is omitted. The explanation is mainly the points of difference from the first embodiment.

As illustrated in FIG. 6, a MOSFET 200 according to the second embodiment includes the high resistance epitaxial layer 2 that includes the first pillar region and the second pillar region as an n⁻-type drift layer, the same as for the MOSFET 100 according to the first embodiment. The second pillar region of the MOSFET 200 according to this embodiment further includes, between the n-type third pillar 5 and the p-type fourth pillar 6, a p-type (same conductivity type as the fourth pillar) fifth pillar 31 adjacent to the n-type third pillar, and an n-type (same conductivity type as the third pillar) sixth pillar 32 adjacent to the fifth pillar 31. The fifth pillar 31 and the sixth pillar 32 are constituted from p-type impurity diffused layers 31A and n-type impurity diffused layers 32A respectively, with the same number of steps in the Y direction as the first through fourth pillars. In the diffusion layer formation layer 80 in each step which is constituted from the impurity diffused layer of each pillar along the X direction, the gross quantity of p-type impurities in the impurity diffused layer 31A of the p-type fifth pillar 31 and the gross quantity of n-type impurities in the impurity diffused layer 32A of the n-type sixth pillar 32 are each less than the gross quantity of n-type impurities in the n-type impurity diffused layer 5A of the n-type third pillar 5, and greater than the gross quantity of p-type impurities in the p-type impurity diffused layer 6A of the p-type fourth pillar 6. Also, the gross quantity of p-type impurities in the impurity diffused layer 31A of the p-type fifth pillar 31 is set to be equal to the gross quantity of n-type impurities in the impurity diffused layer 32A of the n-type sixth pillar 32. The MOSFET 200 according to this embodiment differs from the MOSFET 100 according to the first embodiment in the above point in the second pillar region, and is otherwise the same.

FIG. 7A is a schematic cross-sectional view of the main parts of a portion of the manufacturing process of the second pillar region of the MOSFET 200 according to this embodiment, corresponding to FIG. 2A of the first embodiment, illustrating the n-type and the p-type impurity injection layers for forming the n-type and the p-type impurity diffused layers that constitute the first through sixth pillars according to this embodiment. FIG. 7B is an enlarged view of the portion F in FIG. 7A. The n-type first pillar 3, the p-type second pillar 4, the n-type third pillar 5, and the p-type fourth pillar 6 according to this embodiment have the same structure as the n-type first pillar 3, the p-type second pillar 4, the n-type third pillar 5, and the p-type fourth pillar 6 according to the first embodiment, as described above. Therefore, in the diffusion layer formation layer 80 of each step, the widths in the X direction of the n-type impurity injection layer 3B of the first pillar 3, the p-type impurity injection layer 4B of the p-type second pillar 4, the n-type impurity injection layer 5B of the n-type third pillar 5, and the p-type impurity injection layer 6B of the p-type fourth pillar 6 according to this embodiment are the same as the widths in the X direction of the n-type impurity injection layer 3B of the n-type first pillar 3, the p-type impurity injection layer 4B of the p-type second pillar 4, the n-type impurity injection layer 5B of the n-type third pillar 5, and the p-type impurity injection layer 6B of the p-type fourth pillar 6 according to the first embodiment.

Between the n-type impurity injection layer 5B that is the origin of the n-type third pillar 5 and the p-type impurity injection layer 6B that is the origin of the p-type fourth pillar 6 in the second pillar region according to this embodiment, a p-type impurity injection layer 31B that is the origin of the p-type fifth pillar 31 is formed adjacent to and separated from the n-type impurity injection layer 5B of the n-type third pillar 5. The p-type impurity injection layer 31B is formed in the same p-type impurity injection process as the p-type impurity injection layer 4B of the p-type second pillar 4. In addition, an n-type impurity injection layer 32B that is the origin of the n-type sixth pillar 32 is formed adjacent to and separated from the p-type impurity injection layer 31B of the p-type fifth pillar 31. The n-type impurity injection layer 32B is formed in the same n-type impurity injection process as the n-type impurity injection layer 3B of the n-type first pillar 3.

The widths in the X direction of the p-type impurity injection layer 31B of the p-type fifth pillar and the n-type impurity injection layer 32B of the n-type sixth pillar are both W. In this way, in the diffusion layer formation layer 80 of each step, the gross quantity of p-type impurities in the third pillar 5 side half (the portion corresponding to the width 0.5×W of the impurity diffused layer) of the p-type impurity diffused layer 31A of the p-type fifth pillar 31 and the gross quantity of n-type impurities in the fifth pillar side half (the portion corresponding to 0.5×W) of the n-type impurity diffused layer 5A of the n-type third pillar 5 are equal. The gross quantity of p-type impurities in the sixth pillar side half (the portion corresponding to the width 0.5×W of the impurity diffused layer) of the p-type impurity diffused layer 31A of the p-type fifth pillar 31 and the gross quantity of n-type impurities in the fifth pillar side half (the portion corresponding to 0.5×W) of the n-type impurity diffused layer 32A of the n-type sixth pillar 32 are equal. In addition, the gross quantity of n-type impurities in the fourth pillar side half (the portion corresponding to the width 0.5×W of the impurity diffused layer) of the n-type impurity diffused layer 32A of the n-type sixth pillar 32 and the gross quantity of p-type impurities in the p-type impurity diffused layer 6A of the p-type fourth pillar 6 are equal. As a result of the above, the gross quantity of n-type impurities and the gross quantity of p-type impurities in the whole second pillar region are equal, so a pseudo-undoped state is achieved.

Also, in this embodiment, in the second pillar region, the gross quantity of n-type impurities in the n-type impurity diffused layer 5A of the third pillar 5 is set to be less than the gross quantity of n-type impurities in the n-type impurity diffused layer 3A of the first pillar 3 and the gross quantity of p-type impurities in the p-type impurity diffused layer 4A of the second pillar 4. Also, the gross quantity of p-type impurities in the p-type impurity diffused layer 6A of the fourth pillar is set to be less than the gross quantity of n-type impurities in the n-type impurity diffused layer 5A of the third pillar. In addition, the gross quantity of the p-type impurities in the p-type impurity diffused layer 31A of the p-type fifth pillar 31 and the gross quantity of the n-type impurities in the n-type impurity diffused layer 32A of the n-type sixth pillar 32 are set to be less than the gross quantity of the n-type impurities in the n-type impurity diffused layer 5A of the third pillar 5, and greater than the gross quantity of the p-type impurities in the p-type impurity diffused layer 6A of the p-type fourth pillar 6. Therefore, in the second pillar region according to this embodiment, the portion where the n-type third pillar 5 and the p-type fifth pillar 31 are in opposition, the portion where the p-type fifth pillar 31 and the n-type sixth pillar 32 are in opposition, and the portion where the n-type sixth pillar 32 and the p-type fourth pillar 6 are in opposition have the same structure as the portion D according to the first embodiment where the third pillar 5 and the fourth pillar 6 are in opposition.

In this embodiment also, in the second pillar region, at the portion D where adjacent n-type pillars and p-type pillars are in opposition, the gross quantity of n-type impurities in the n-type impurity diffused layer of the n-type pillar and the gross quantity of p-type impurities in the p-type impurity diffused layer of the p-type pillar are set to be lower than the gross quantity of impurities in the impurity diffused layers of the n-type first pillar 3 and the p-type second pillar 4 of the first pillar region, while maintaining the equality of the gross quantity of the n-type impurities and the gross quantity of the p-type impurities. Therefore, as illustrated in FIG. 5, in the portion D where the n-type pillar and the p-type pillar are in opposition in the second pillar region depletion layers can spread more easily than in the portion B where the n-type first pillar 3 and the p-type second pillar 4 are in opposition in the first pillar region, so the withstand voltage is further increased. If the variation in the width of the apertures of the mask for forming the p-type pillars is restricted to be within the area where the withstand voltage of the portion D where adjacent n-type pillars and p-type pillars are in opposition in the second pillar region is higher than the withstand voltage of the portion B where the first pillar 3 and the second pillar 4 are in opposition in the first pillar region, then breakdown will always occur first in the first pillar region before the second pillar region. The MOSFET 200 according to this embodiment can suppress the reduction in withstand voltage in the termination region due to manufacturing variation in the manufacture of the super junction structure, similar to the MOSFET 100 according to the first embodiment, so the avalanche resistance is improved.

In this embodiment, as an example, the gross quantity of p-type impurities in the p-type impurity diffused layer 6A of the fourth pillar was set to be ¼ times the gross quantity of n-type impurities in the n-type impurity diffused layer 3A of the first pillar 3 and the gross quantity of p-type impurities in the p-type impurity diffused layer 4A of the second pillar 4, but as in the first embodiment these may be set to be not more than half.

The MOSFET 200 according to this embodiment was explained using an example in which there is a pair of the p-type fifth pillar 31 and the n-type sixth pillar 32 between the n-type third pillar 5 and the p-type fourth pillar 6 in the second pillar region, but it is also possible to have two or more pairs of the p-type fifth pillar 31 and the n-type sixth pillar 32.

### Third Embodiment

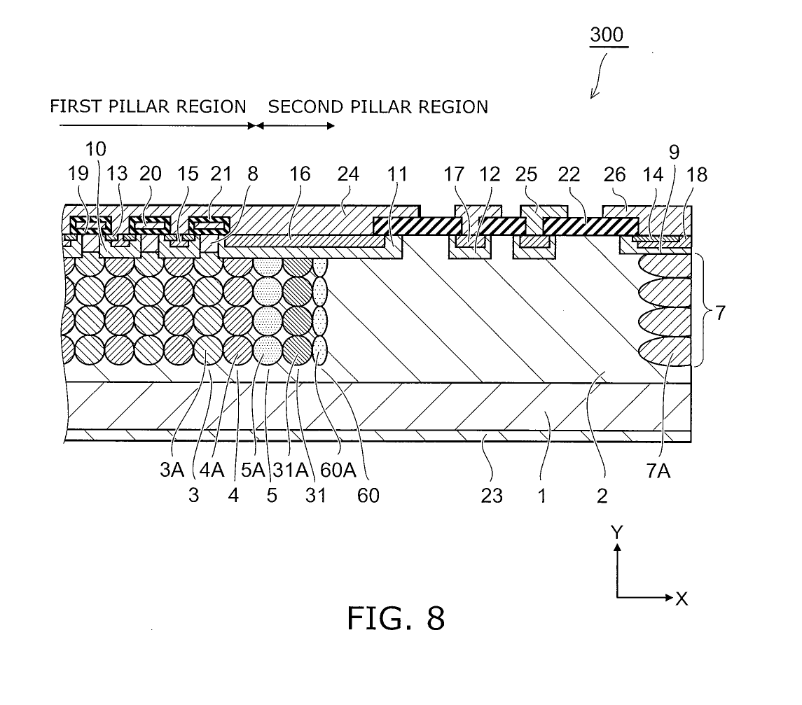

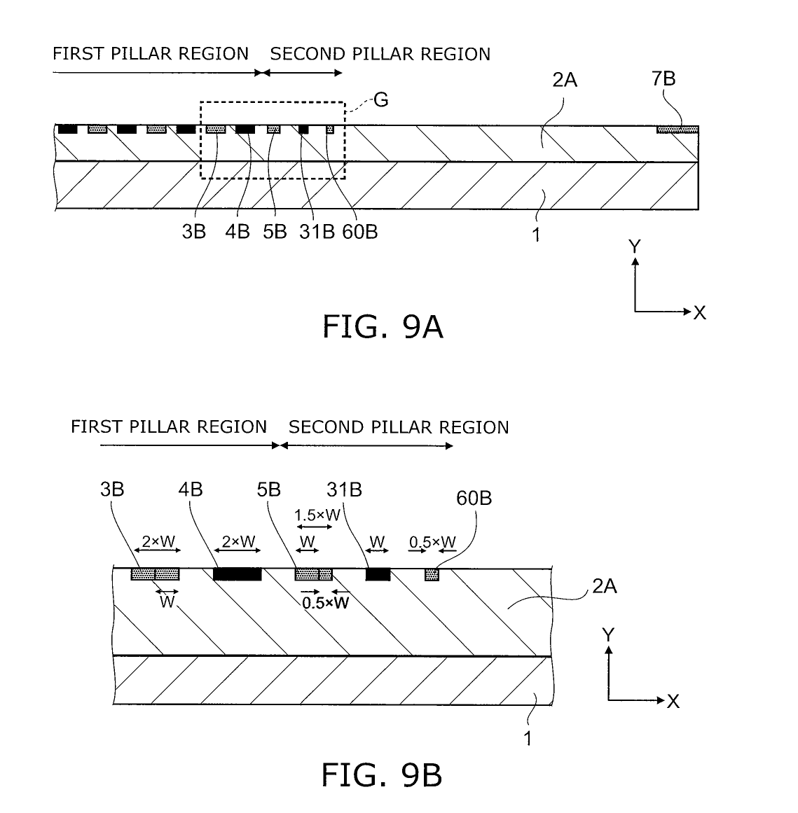

The following is an explanation of a power semiconductor device 300 according to a third embodiment using FIGS. 8 and 9. FIG. 8 is a schematic cross-sectional view of the main parts of the power semiconductor device according to the third embodiment. FIGS. 9A and 9B illustrate a part of the manufacturing process of the power semiconductor device according to the third embodiment, FIG. 9A is a schematic cross-sectional view of the main parts, and FIG. 9B is an enlarged view of the portion G in FIG. 9A. Parts having the same constitution as the constitution explained for the first embodiment use the same reference number or symbol, and their explanation is omitted. The points of difference from the first embodiment are mainly explained.

As illustrated in FIG. 8, a MOSFET 300 according to the third embodiment includes the high resistance epitaxial layer 2 that includes the first pillar region and the second pillar region as an n⁻-type drift layer, the same as for the MOSFET 100 according to the first embodiment. The second pillar region of the MOSFET 300 according to this embodiment includes the p-type (the conductivity type opposite to that of the third pillar) fifth pillar 31 adjacent to the n-type third pillar, between the n-type third pillar 5 and an n-type fourth pillar 60. The fifth pillar 31 is constituted from the p-type impurity diffused layers 31A with the same number of steps in the Y direction as the first through fourth pillars. In the diffusion layer formation layer 80 in each step that is constituted from the impurity diffused layers of each pillar along the X direction, the gross quantity of p-type impurities in the impurity diffused layers 31A of the p-type fifth pillar 31 is less than the gross quantity of the n-type impurities in the n-type impurity diffused layer 5A of the n-type third pillar 5, and greater than the gross quantity of the p-type impurities in the p-type impurity diffused layer 60A of the n-type fourth pillar 60. The MOSFET 300 according to this embodiment differs from the MOSFET 100 according to the first embodiment in that the conductivity type of the fourth pillar 60 is changed from p-type to n-type, and the p-type fifth pillar 31 is provided between the third pillar 5 and the fourth pillar 6, as described above.

FIG. 9A is a schematic cross-sectional view of the main parts of a portion of the manufacturing process of the second pillar region of the MOSFET 300 according to this embodiment, corresponding to FIG. 2A for the first embodiment, and is a cross-sectional view illustrating the n-type and the p-type impurity injection layers that are the origin for forming the n-type and the p-type impurity diffused layers that constitute the first through fifth pillars of this embodiment. FIG. 9B is an enlarged view of the portion G in FIG. 9A. The n-type first pillar 3, the p-type second pillar 4, the n-type third pillar 5, and the n-type fourth pillar 60 according to this embodiment have the same structure as the n-type first pillar 3, the p-type second pillar 4, the n-type third pillar 5, and the p-type fourth pillar 6 according to the first embodiment, as described above. Therefore, in the diffusion layer formation layer 80 of each step, the widths in the X direction of the n-type impurity injection layer 3B of the n-type first pillar 3, the p-type impurity injection layer 4B of the p-type second pillar 4, the n-type impurity injection layer 5B of the n-type third pillar 5, and the n-type impurity injection layer 60B of the n-type fourth pillar are the same as the widths of the n-type impurity injection layer 3B of the n-type first pillar 3, the p-type impurity injection layer 4B of the p-type second pillar 4, the n-type impurity injection layer 5B of the n-type third pillar 5, and the p-type impurity injection layer 6B of the p-type fourth pillar 6 according to the first embodiment. However, the n-type fourth pillar 60 according to this embodiment has a different conductivity type than the p-type fourth pillar 6 according to the first embodiment, so the n-type impurity injection layer 60B of the n-type fourth pillar 60 according to this embodiment is formed in the same n-type impurity injection process as the n-type impurity injection layer 3B of the n-type first pillar 3.

Between the n-type impurity injection layer 5B that is the origin of the n-type third pillar 5 and the n-type impurity injection layer 60B that is the origin of the n-type fourth pillar 60 in the second pillar region according to this embodiment, the p-type impurity injection layer 31B that is the origin of the p-type fifth pillar 31 is formed, adjacent to and separated from the n-type impurity injection layer 5B of the n-type third pillar 5. The p-type impurity injection layer 31B of the p-type fifth pillar 31 is formed in the same p-type impurity injection process as the p-type impurity injection layer 4B of the p-type second pillar 4.

The width in the X direction of the p-type impurity injection layer 31B of the p-type fifth pillar 31 is W. As a result, in the diffusion layer formation layer 80 of each step, the gross quantity of p-type impurities in the n-type third pillar 5 side half (the portion corresponding to the width 0.5×W of the impurity diffused layer) of the p-type impurity diffused layer 31A of the p-type fifth pillar 31 and the gross quantity of n-type impurities in the fifth pillar side half (the portion corresponding to 0.5×W) of the n-type impurity diffused layer 5A of the n-type third pillar 5 are equal. The gross quantity of p-type impurities in the fourth pillar 60 side half (the portion corresponding to the width 0.5×W of the impurity diffused layer) of the p-type impurity diffused layer 31A of the p-type fifth pillar 31 and the gross quantity of n-type impurities in the n-type impurity diffused layer 60A of the n-type fourth pillar 60 are equal. From the above, the gross quantity of n-type impurities and the gross quantity of p-type impurities in the second pillar region as a whole are equal, so a pseudo-undoped state is achieved.

Also, in this embodiment, in the second pillar region, the gross quantity of n-type impurities in the n-type impurity diffused layer 5A of the third pillar 5 is set to be less than the gross quantity of the n-type impurities in the n-type impurity diffused layer 3A of the first pillar 3 and the gross quantity of p-type impurities in the p-type impurity diffused layer 4A of the second pillar 4. Also, the gross quantity of the n-type impurities in the n-type impurity diffused layer 6A of the fourth pillar is set to be less than the gross quantity of the n-type impurities in the n-type impurity diffused layer 5A of the third pillar. In addition, the gross quantity of the p-type impurities in the p-type impurity diffused layer 31A of the p-type fifth pillar 31 is set to be less than the gross quantity of the n-type impurities in the n-type impurity diffused layer 5A of the n-type third pillar 5, and greater than the gross quantity of the n-type impurities in the n-type impurity diffused layer 60A of the n-type fourth pillar 60. Therefore, in the second pillar region according to this embodiment, the portion where the n-type third pillar 5 and the p-type fifth pillar 31 are in opposition and the portion where the p-type fifth pillar 31 and the n-type fourth pillar 60 are in opposition have the same structure as the portion D where the n-type third pillar 5 and the p-type fourth pillar 6 are in opposition according to the first embodiment.

In this embodiment also, in the second pillar region the gross quantity of n-type impurities in the n-type impurity diffused layers of the n-type pillars and the gross quantity of p-type impurities in the p-type impurity diffused layers of the p-type pillars are set to be lower than the gross quantity of n-type impurities in the n-type impurity diffused layers 3A of the n-type first pillar 3 and the gross quantity of p-type impurities in the p-type impurity diffused layers 4A of the p-type second pillar 4 in the first pillar region, while maintaining the equality of the gross quantity of n-type impurities and the gross quantity of p-type impurities in the portion D where the adjacent n-type pillars and p-type pillars are in opposition. Therefore, as illustrated in FIG. 5, depletion layers can spread more easily in the portion D where the adjacent n-type pillars and p-type pillars are in opposition in the second pillar region compared with the portion B where the n-type first pillar 3 and the p-type second pillar 4 are in opposition in the first pillar region, so the withstand voltage is further increased. If the variation in the width of the apertures of the mask for forming the p-type pillars is restricted to be within the area where the withstand voltage of the portion D where the adjacent n-type pillars and p-type pillars are in opposition in the second pillar region is higher than the withstand voltage of the portion B where the first pillar 3 and the second pillar 4 are in opposition in the first pillar region, breakdown will always occur first in the first pillar region before the second pillar region. The MOSFET 300 according to this embodiment can suppress the reduction in withstand voltage in the termination region due to manufacturing variation in the super junction structure, the same as for the MOSFET 100 according to the first embodiment, so the avalanche resistance is improved.

In this embodiment, as an example, the gross quantity of n-type impurities in the n-type impurity diffused layer 60A of the fourth pillar was set to be 1/4 times the gross quantity of the n-type impurities in the n-type impurity diffused layer 3A of the first pillar 3 and the gross quantity of the p-type impurities in the p-type impurity diffused layer 4A of the second pillar 4, these may be set to be not more than half, the same as for the first embodiment.

### Fourth Embodiment

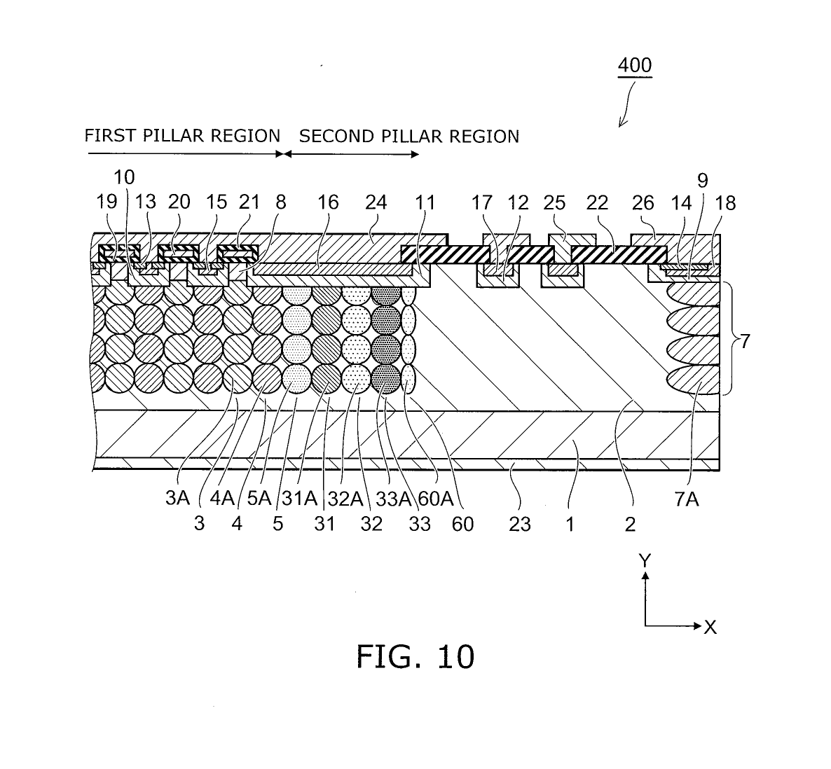

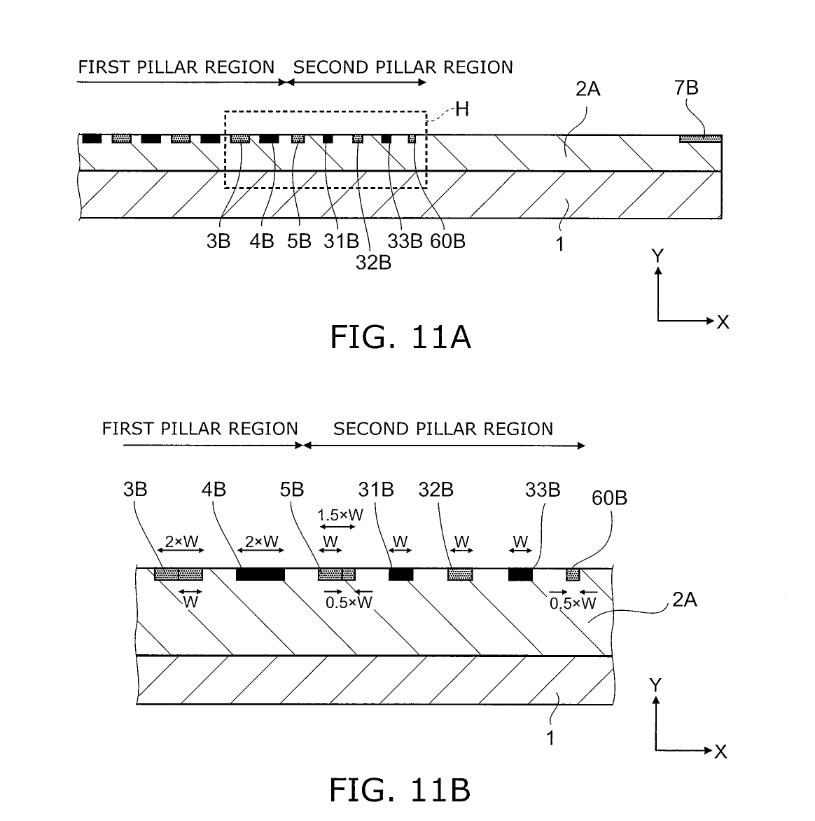

The following in an explanation of a power semiconductor device 400 according to a fourth embodiment, using FIGS. 10 and 11. FIG. 10 is a schematic cross-sectional view of the main parts of the power semiconductor device according to the fourth embodiment. FIGS. 11A and 11B illustrate a portion of the manufacturing process of the power semiconductor device according to the fourth embodiment, FIG. 11A is a schematic cross-sectional view of the main parts, and FIG. 11B is an enlarged view of the portion H in FIG. 11A. Parts with the same constitution as the constitution explained for the third embodiment use the same reference number or symbol, and their explanation is omitted. The points of difference from the third embodiment are mainly explained.

As illustrated in FIG. 10, a MOSFET 400 according to the fourth embodiment includes the high resistance epitaxial layer 2 that includes the first pillar region and the second pillar region as an n⁻-type drift layer, the same as for the MOSFET 300 according to the third embodiment. The second pillar region of the MOSFET 400 according to this embodiment further includes, between the p-type fifth pillar 31 and the n-type fourth pillar 60 in the second pillar region of the MOSFET 300 according to the third embodiment, a pair of pillars that includes the n-type sixth pillar 32 and a p-type seventh pillar 33. The n-type sixth pillar 32 and the p-type seventh pillar 33 are constituted from the n-type impurity diffused layers 32A and p-type impurity diffused layers 33A, with the same number of steps in the Y direction as the first through fourth pillars. In the diffusion layer formation layer 80 which is constituted from the impurity diffused layer of each pillar along the X direction in each step, the gross quantity of n-type impurities in the impurity diffused layer 32A of the n-type sixth pillar 32 and the gross quantity of p-type impurities in the impurity diffused layer 33A of the p-type seventh pillar 33 are equal to the gross quantity of p-type impurities in the p-type impurity diffused layer 31A of the p-type fifth pillar. The MOSFET 400 according to this embodiment differs from the MOSFET 300 according to the third embodiment in the above point.

FIG. 11A is a schematic cross-sectional view of the main parts of a portion of the manufacturing process of the second pillar region of the MOSFET 400 according to this embodiment, corresponding to FIG. 2A of the first embodiment, illustrating the n-type and the p-type impurity injection layers for forming the n-type and the p-type impurity diffused layers that constitute the first through seventh pillars according to this embodiment. FIG. 11B is an enlarged view of the portion H in FIG. 11A. The n-type first pillar 3, the p-type second pillar 4, the n-type third pillar 5, the n-type fourth pillar 60, and the p-type fifth pillar 31 according to this embodiment have the same structure as the n-type first pillar 3, the p-type second pillar, the n-type third pillar 5, the n-type fourth pillar 60, and the p-type fifth pillar 31 according to the third embodiment, as described above. Therefore, in the diffusion layer formation layer 80 of each step, the widths in the X direction of the n-type impurity injection layer 3B of the n-type first pillar 3, the p-type impurity injection layer 4B of the p-type second pillar 4, the n-type impurity injection layer 5B of the n-type third pillar 5, the n-type impurity injection layer 60B of the n-type fourth pillar 60, and the p-type impurity injection layer 31B of the p-type fifth pillar 31 are the same as the widths of the n-type impurity injection layer 3B of the n-type first pillar 3, the p-type impurity injection layer 4B of the p-type second pillar 4, the n-type impurity injection layer 5B of the n-type third pillar 5, the n-type impurity injection layer 60B of the n-type fourth pillar 60, and the p-type impurity injection layer 31B of the p-type fifth pillar 31 according to the third embodiment.

Between the p-type impurity injection layer of the p-type fifth pillar 31 and the n-type impurity injection layer 60B of the n-type fourth pillar 60 in the second pillar region according to this embodiment, the n-type impurity injection layer 32B that is the origin of the n-type sixth pillar 32 is formed, adjacent to and separated from the p-type impurity injection layer 31B of the p-type fifth pillar 31. The n-type impurity injection layer 32B of the sixth pillar 32 is formed in the same n-type impurity injection process as the n-type impurity injection layer 3B of the n-type first pillar 3. Also, the p-type impurity injection layer 33B that is the origin of the p-type seventh pillar 33 is formed adjacent to and separated from the n-type impurity injection layer 32B of the n-type sixth pillar 32. The p-type impurity injection layer 33B is formed in the same p-type impurity injection process as the p-type impurity injection layer 4B of the p-type second pillar 4.

The widths in the X direction of the n-type impurity injection layer 32B of the n-type sixth pillar 32 and the p-type impurity injection layer 33B of the p-type seventh pillar 33 are both W. In this way, in the diffusion layer formation layer 80 of each step, the gross quantity of p-type impurities in the third pillar 5 side half (the portion corresponding to the width 0.5×W of the impurity diffused layer) of the p-type impurity diffused layer 31A of the p-type fifth pillar 31 and the gross quantity of n-type impurities in the fifth pillar side half (the portion corresponding to 0.5×W) of the n-type impurity diffused layer 5A of the n-type third pillar 5 are equal. The gross quantity of p-type impurities in the sixth pillar side half (the portion corresponding to the width 0.5×W of the impurity diffused layer) of the p-type impurity diffused layer 31A of the p-type fifth pillar 31 and the gross quantity of n-type impurities in the fifth pillar side half (the portion corresponding to 0.5×W) of the n-type impurity diffused layer 32A of the n-type sixth pillar 32 are equal. The gross quantity of n-type impurities in the seventh pillar 33 side half (the portion corresponding to the width 0.5×W of the impurity diffused layer) of the n-type impurity diffused layer 32A of the n-type sixth pillar 32 and the gross quantity of p-type impurities in the sixth pillar side half (the portion corresponding to 0.5×W) of the p-type impurity diffused layer 33A of the p-type seventh pillar 33 are equal. In addition, the gross quantity of p-type impurities in the fourth pillar side half (the portion corresponding to the width 0.5×W of the impurity diffused layer) of the p-type impurity diffused layer 33A of the p-type seventh pillar 33 and the gross quantity of n-type impurities in the n-type impurity diffused layer 60A of the n-type fourth pillar 60 are equal. As a result of the above, the gross quantity of n-type impurities and the gross quantity of p-type impurities in the whole second pillar region are equal, so a pseudo-undoped state is achieved.

Also, in this embodiment, in the second pillar region, the gross quantity of n-type impurities in the n-type impurity diffused layer 5A of the third pillar 5 is set to be less than the gross quantity of n-type impurities in the n-type impurity diffused layer 3A of the first pillar 3 and the gross quantity of p-type impurities in the p-type impurity diffused layer 4A of the second pillar 4. Also, the gross quantity of n-type impurities in the n-type impurity diffused layer 60A of the fourth pillar 60 is set to be less than the gross quantity of n-type impurities in the n-type impurity diffused layer 5A of the third pillar 5. In addition, the gross quantity of the p-type impurities in the p-type impurity diffused layer 31A of the p-type fifth pillar 31, the gross quantity of the n-type impurities in the n-type impurity diffused layer 32A of the n-type sixth pillar 32, and the gross quantity of the p-type impurities in the p-type impurity diffused layer 33A of the p-type seventh pillar 33 are set to be less than the gross quantity of the n-type impurities in the n-type impurity diffused layer 5A of the third pillar 5, and greater than the gross quantity of the n-type impurities in the n-type impurity diffused layer 60A of the n-type fourth pillar 60. Therefore, in the second pillar region according to this embodiment, the portion where the n-type third pillar 5 and the p-type fifth pillar 31 are in opposition, the portion where the p-type fifth pillar 31 and the n-type sixth pillar 32 are in opposition, the portion where the n-type sixth pillar 32 and the p-type seventh pillar 33 are in opposition, and the portion where the p-type seventh pillar 33 and the n-type fourth pillar 60 are in opposition have the same structure as the portion D according to the first embodiment where the third pillar 5 and the fourth pillar 6 are in opposition.

In this embodiment also, in the second pillar region the gross quantity of n-type impurities in the n-type impurity diffused layers of the n-type pillars and the gross quantity of p-type impurities in the p-type impurity diffused layers of the p-type pillars are set to be lower than the gross quantity of n-type impurities in the n-type impurity diffused layers 3A of the n-type first pillar 3 and the gross quantity of p-type impurities in the p-type impurity diffused layers 4A of the p-type second pillar 4 in the first pillar region, while maintaining the equality of the gross quantity of n-type impurities and the gross quantity of p-type impurities in the portions D where the adjacent n-type pillars and p-type pillars are in opposition. Therefore, as illustrated in FIG. 5, in the portion D where the n-type pillars and the p-type pillars are in opposition in the second pillar region, depletion layers can spread more easily than in the portion B where the n-type first pillar 3 and the p-type second pillar 4 are in opposition in the first pillar region, so the withstand voltage is further increased. If the variation in the width of the apertures of the mask for forming the p-type pillars is restricted to be within the area where the withstand voltage of the portion D where the adjacent n-type pillars and p-type pillars are in opposition in the second pillar region is higher than the withstand voltage of the portion B where the first pillar 3 and the second pillar 4 are in opposition in the first pillar region, breakdown will always occur first in the first pillar region before the second pillar region. The MOSFET 400 according to this embodiment can minimize the reduction in withstand voltage in the termination region due to manufacturing variation in the manufacture of the super junction structure, similar to the MOSFET 100 according to the first embodiment, so the avalanche resistance is improved.

The MOSFET 400 according to this embodiment was explained using an example in which there is a pair of the n-type sixth pillar 32 and the p-type seventh pillar 33 between the p-type fifth pillar 31 and the n-type fourth pillar 60 in the second region, but it is also possible to have two or more pairs of the n-type sixth pillar 32 and the seventh pillar 33.

In this embodiment, as an example, the gross quantity of p-type impurities in the n-type impurity diffused layer 60A of the fourth pillar 60 was set to be 1/4 times the gross quantity of the n-type impurities in the n-type impurity diffused layer 3A of the first pillar 3 and the gross quantity of the p-type impurities in the p-type impurity diffused layer 4A of the second pillar 4, but these may be set to be not more than half, the same as for the first embodiment.

The first through fourth embodiments as described above were discussed using the gross quantity of the n-type and the p-type impurities in each impurity diffused layer, but these descriptions also include the use of the net quantity of n-type and p-type impurities. In the following embodiments, the descriptions use the net quantity of n-type and p-type impurities instead of the gross quantity of n-type and p-type impurities.

### Fifth Embodiment

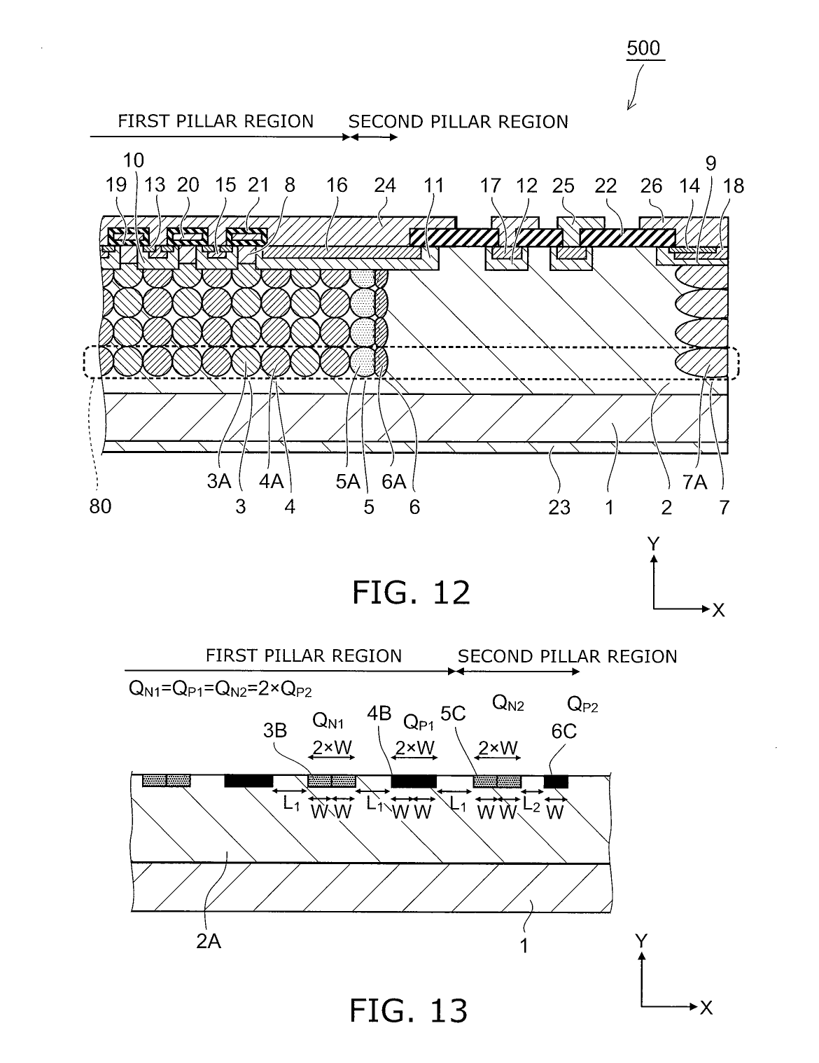

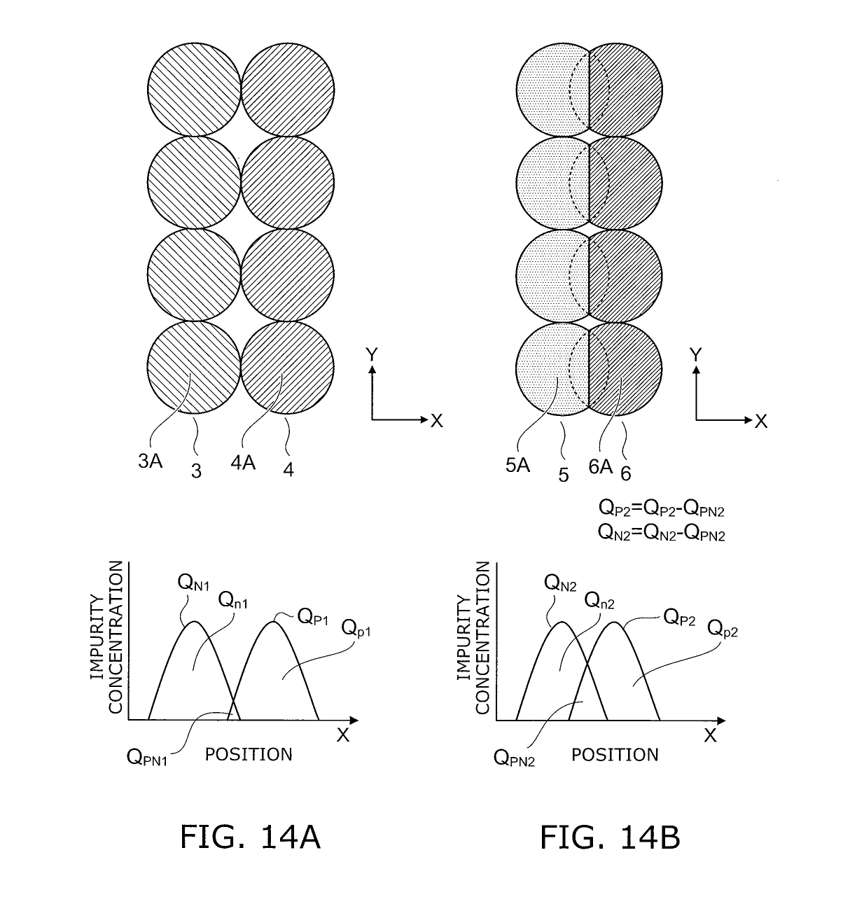

The following is an explanation of a power semiconductor device 500 according to a fifth embodiment using FIGS. 12 through 14. FIG. 12 is a schematic cross-sectional view of the main parts of the power semiconductor device according to the fifth embodiment. FIG. 13 illustrates a part of the manufacturing process of the power semiconductor device according to the fifth embodiment, and is a schematic cross-sectional view of the main parts corresponding to FIG. 2B. FIG. 14A is a drawing for schematically explaining the main parts of the first pillar region, and FIG. 14B is a drawing for schematically explaining the main parts of the second pillar region of the power semiconductor device according to the fifth embodiment. Portions having the same constitution as the constitution explained in the first embodiment use the same reference number or symbol, and their explanation is omitted. The explanation is mainly the points of difference from the first embodiment.

A MOSFET 500 according to this embodiment includes the high resistance epitaxial layer 2 that includes the first pillar region and the second pillar region as an n-type drift layer, the same as for the MOSFET 100 according to the first embodiment, but differs from the MOSFET 100 according to the first embodiment in the following points.

In the MOSFET 500 according to this embodiment, in the diffusion layer formation layer 80 of each step, the n-type impurity diffused layer 5A and the p-type impurity diffused layer 6A of the n-type third pillar 5 and the p-type fourth pillar 6 in the second pillar region overlap in the X direction, and form an impurity compensation region as described previously. This impurity compensation region was ignored in the explanations of the first through fourth embodiments. In other words, in this embodiment, there is a first impurity compensation region in which n-type impurities and p-type impurities are mixed in the portion where the n-type impurity diffused layer 3A of the n-type first pillar 3 and the p-type impurity diffused layer 4A of the p-type second pillar 4 overlap with each other in the first pillar region. Likewise, there is a second impurity compensation region in which n-type impurities and p-type impurities are mixed in the portion where the impurity diffused layer 5A of the third pillar 5 and the impurity diffused layer 6A of the fourth pillar 6 overlap in the X direction.

Here, as illustrated in FIG. 12, the width in the X direction of the second impurity compensation region is formed to be wider than the width in the X direction of the first impurity compensation region. Near the center of the impurity compensation region, where the n-type impurity concentration and the p-type impurity concentration are equal, a p-n junction of the adjacent pillars is formed. In FIG. 12, for ease of explanation, the first impurity compensation region formed between the first pillar and the second pillar has been omitted from the drawing as so being small that it can be ignored. The overlapping portion indicated with broken lines in the third pillar and the fourth pillar is the second impurity compensation region.

FIG. 13 illustrates a part of the manufacturing process of the first pillar region and the second pillar region, and in this embodiment, ion implantation is carried out so that the impurity injection layers of each pillar has the following widths, and each pillar is formed. The n-type impurity injection layer 5C of the n-type third pillar 5 in the second pillar region is formed with a width of 2×W, which is the same as the width in the X direction of the n-type impurity injection layer 3B of the n-type first pillar 3 and the p-type impurity injection layer 4B of the p-type second pillar 4 in the first pillar region. The p-type impurity injection layer 6C of the p-type fourth pillar 6 in the second pillar region is formed with a width of W, which is half the width in the X direction of the n-type impurity injection layer 3B of the n-type first pillar 3 and the p-type impurity injection layer 4B of the p-type second pillar 4 in the first pillar region.

Although omitted from the drawings, in this embodiment, the widths of each of the impurity injection layers 3B, 4B, 5C, and 6C are set so that at the portion where the n-type impurity diffused layer 3A of the first pillar 3 and the p-type impurity diffused layer 4A of the second pillar 4 are in opposition, the portion where the p-type impurity diffused layer 4A of the second pillar 4 and the n-type impurity diffused layer 5A of the third pillar 5 are in opposition, and the portion where the n-type impurity diffused layer 5A of the third pillar 5 and the p-type impurity diffused layer 6A of the fourth pillar 6 are in opposition, the gross quantity of n-type impurities and the gross quantity of p-type impurities are equal.

Also, the n-type impurity injection layer 3B of the first pillar 3 and the p-type impurity injection layer 4B of the second pillar 4 are formed so that they are separated from each other by a gap L1.

Likewise, the p-type impurity injection layer 4B of the second pillar 4 and the n-type impurity injection layer 5C of the third pillar 5 are formed so that they are separated from each other by the gap L1. In contrast, in the second pillar region the n-type impurity injection layer 5C of the n-type third pillar 5 and the p-type impurity injection layer 6C of the p-type fourth pillar 6 are formed so that they are separated from each other by a gap L2 which is narrower than the gap L1.

As described above, in the MOSFET 500 according to this embodiment, in the second pillar region, the gap L2 between the n-type impurity injection layer 5C of the third pillar 5 and the p-type impurity injection layer 6C of the fourth pillar 6 is formed to be narrower than the gap L1 between the n-type impurity injection layer 3B of the first pillar 3 and the p-type impurity injection layer 4B of the second pillar 4 in the first pillar region. In this way, the impurity diffused layers formed from the impurity injection layers by annealing, which is carried out later, join in the Y direction (the stacking direction) and the pillars are formed. The overlap in the X direction of the n-type impurity diffused layer 5A of the third pillar 5 and the p-type impurity diffused layer 6A of the fourth pillar 6 is greater than the overlap in the X direction of the n-type impurity diffused layer 3A of the first pillar 3 and the p-type impurity diffused layer 4A of the second pillar 4. In other words, the width (the width of mutual overlap) in the X direction of the second impurity compensation region in the second pillar region is formed to be wider than the width (the width of mutual overlap) in the X direction of the first impurity compensation region in the first pillar region. In this respect, the MOSFET 500 according to this embodiment differs from the MOSFET 100 according to the first embodiment.

FIG. 14A is a drawing for schematically explaining the main parts of the first pillar region, and FIG. 14B is a drawing for schematically explaining the main parts of the second pillar region of this embodiment. In FIG. 14A and FIG. 14B, the top part schematically illustrates the state of overlap in the X direction of each impurity diffused layer of adjacent pillars, and the bottom part schematically illustrates the impurity concentration distribution profile in the X direction.

In the first pillar region, the n-type impurity diffused layer 3A of the n-type first pillar 3 has a gross quantity of n-type impurities of Q_{N1}, and the p-type impurity diffused layer 4A of the second pillar 4 has a gross quantity of p-type impurities of Q_{P1}, and have a concentration profile in the X direction as illustrated in the bottom part of FIG. 14A. Here, in the first impurity compensation region (the region in the drawing where the concentration profiles overlap in the X direction), if the quantity of the n-type impurities and the quantity of the p-type impurities eliminated by the impurity compensation is Q_{PN1}, the net quantity of n-type impurities in the n-type impurity diffused layer 3A of the n-type first pillar 3 is Qₙ₁=Q_{N1}−Q_{PN1}, and likewise the net quantity of p-type impurities in the p-type impurity diffused layer 4A of the p-type second pillar 4 is Qₙ₁=Q_{N1}−Q_{PN1}. Here, in the first pillar region, for ease of explanation, it is considered that the first impurity compensation region can be ignored, so it is considered that the gross quantity of impurities and the net quantity of impurities are approximately equal.

In contrast, in the second pillar region, as illustrated in the top part of FIG. 14B, the overlap in the X direction of the n-type impurity diffused layer 5A of the third pillar 5 and the p-type impurity diffused layer 6A of the fourth pillar 6 is large compared with the n-type impurity diffused layer 3A of the first pillar 3 and the p-type impurity diffused layer 4A of the second pillar 4, as indicated by the broken lines. In other words, the width in the X direction of the second impurity compensation region is greater than the width in the X direction of the first impurity compensation region. In the second pillar region, the n-type impurity diffused layer 5A of the n-type third pillar 5 has a gross quantity of n-type impurities of Q_{N2}, and the p-type impurity diffused layer 6A of the p-type fourth pillar 6 has a gross quantity of p-type impurities of Q_{P2}, and each has a concentration profile in the X direction as shown in the bottom part of FIG. 14B.

Here, if the quantity of n-type impurities and the quantity of p-type impurities eliminated due to impurity compensation in the second impurity compensation region (the region where the concentration profiles are overlapped in the X direction in the drawing) is Q_{PN2}, the net quantity of n-type impurities in the n-type impurity diffused layer 5A of the n-type third pillar 5 is Qₙ₂=Q_{N2}−Q_{PN2}, and likewise the net quantity of p-type impurities in the p-type impurity diffused layer 6A of the p-type fourth pillar is Qₙ₂=Q_{N2}−Q_{PN2}. The width in the X direction of the second impurity compensation region is greater than the width in the X direction of the first impurity compensation region, so the quantity of the n-type and the p-type impurities eliminated due to impurity compensation is greater in the second impurity compensation region. Therefore, Q_{PN1}<Q_{PN2}.

Also, the gross quantity of impurities is determined by the width of the impurity injection layer. Under the condition that the widths of each impurity injection layer is set as described above, as illustrated in FIG. 13, then there is the following relationship between the gross quantity Q_{N1} of n-type impurities in the n-type impurity diffused layer 3A of the n-type first pillar 3, the gross quantity Q_{P1} of p-type impurities in the p-type impurity diffused layer 4A of the p-type second pillar 4, the gross quantity Q_{N2} of n- type impurities in the n-type impurity diffused layer 5A of the n-type third pillar 5, and the gross quantity Q_{P2} of p-type impurities in the p-type impurity diffused layer 6A of the p-type fourth pillar 6: Q_{N1}=Q_{P1}=Q_{N2}=2×Q_{P2}.

From the above, there is the following relationship between the net quantity Qₙ₁ of n-type impurities in the n-type impurity diffused layer 3A of the n-type first pillar 3, the net quantity Q_{P1} of p-type impurities in the p-type impurity diffused layer 4A of the p-type second pillar 4, the net quantity of Qₙ₂ n-type impurities in the n-type impurity diffused layer 5A of the n-type third pillar 5, and the net quantity Qₚ₂ of p-type impurities in the p-type impurity diffused layer 6A of the p-type fourth pillar 6: Qₙ₁=Qₚ₁>Qₙ₂>Qₚ₂.

In other words, in this embodiment, in the second pillar region at the portion D where adjacent n-type pillars and p-type pillars are in opposition, the net quantity of n-type impurities in the n-type impurity diffused layer of the n-type pillars and the net quantity of p-type impurities in the p-type impurity diffused layer of the p-type pillars are set to be lower than the net quantity of n-type impurities in the n-type impurity diffused layer of the n-type first pillar 3 and the net quantity of p-type impurities in the p-type impurity diffused layer of the p-type second pillar 4 of the first pillar region, while maintaining the equality of the net quantity of the n-type impurities and the net quantity of the p-type impurities. Therefore, as illustrated in FIG. 5, in the portion D where the n-type pillars and the p-type pillars are in opposition in the second pillar region, depletion layers can spread more easily than in the portion B where the n-type first pillar 3 and the p-type second pillar 4 are in opposition in the first pillar region, so the withstand voltage is further increased. If the variation in the width of the apertures of the mask for forming the p-type pillars is restricted to be within the area where the withstand voltage of the portion D where the third pillar 5 and the fourth pillar 6 are in opposition is higher than the withstand voltage of the portion B where the first pillar 3 and the second pillar 4 are in opposition, then breakdown will always occur first in the first pillar region before the second pillar region. The MOSFET 500 according to this embodiment can suppress the reduction in withstand voltage in the termination region due to manufacturing variation in the super junction structure, similar to the MOSFET 100 according to the first embodiment, so the avalanche resistance is improved.

In the top part of FIG. 14B, for ease of explanation, the width in the X direction of the p-type impurity diffused layer 6A of the fourth pillar 6 is illustrated as the same width in the X direction of the n-type impurity diffused layer 5A of the third pillar 5. However, in reality it is narrower than the width in the X direction of the n-type impurity diffused layer 5A of the third pillar 5. Likewise, for the concentration profile of the p-type impurity diffused layer 6A of the fourth pillar 6 shown in the bottom part of FIG. 14B, the width in the X direction of the concentration profile of the p-type impurity diffused layer 6A of the fourth pillar 6 is illustrated as the same width in the X direction of the concentration profile of the n-type impurity diffused layer 5A of the third pillar 5. However, in reality it is narrower than the width in the X direction of the concentration profile of the n-type impurity diffused layer 5A of the third pillar 5.

In this embodiment, the width of the n-type impurity injection layer 3B of the first pillar 3, the width of the p-type impurity injection layer 4B of the second pillar 4, and the width of the n-type impurity injection layer 5C of the third pillar 5 are set to be the same width, and the width of the p-type impurity injection layer 6C of the fourth pillar 6 is set to be half the width of the n-type impurity injection layer 3B of the first pillar 3 and the width of the p-type impurity injection layer 4B of the second pillar 4. In other words, the gross quantity of n-type impurities in the n-type impurity diffused layer 3A of the first pillar 3, the gross quantity of p-type impurities in the p-type impurity diffused layer 4A of the second pillar 4, and the gross quantity of n-type impurities in the n-type impurity diffused layer 5A of the third pillar 5 are set to be equal, and the gross quantity of p-type impurities in the p-type impurity diffused layer 6A of the fourth pillar 6 is set to be half the gross quantity of n-type impurities in the n-type impurity diffused layer 3A of the first pillar 3 and the gross quantity of p-type impurities in the p-type impurity diffused layer 4A of the second pillar 4. However, similar to the first embodiment, in the second pillar region, the gross quantity of n-type impurities in the n-type impurity diffused layer 5A of the third pillar 5 can be set to be less than the gross quantity of n-type impurities in the n-type impurity diffused layer 3A of the first pillar 3 and the gross quantity of p-type impurities in the p-type impurity diffused layer 4A of the second pillar 4. Also, the gross quantity of p-type impurities in the p-type impurity diffused layer 6A of the fourth pillar can be set to be less than half the gross quantity of n-type impurities in the n-type impurity diffused layer 5A of the third pillar.

### Sixth Embodiment

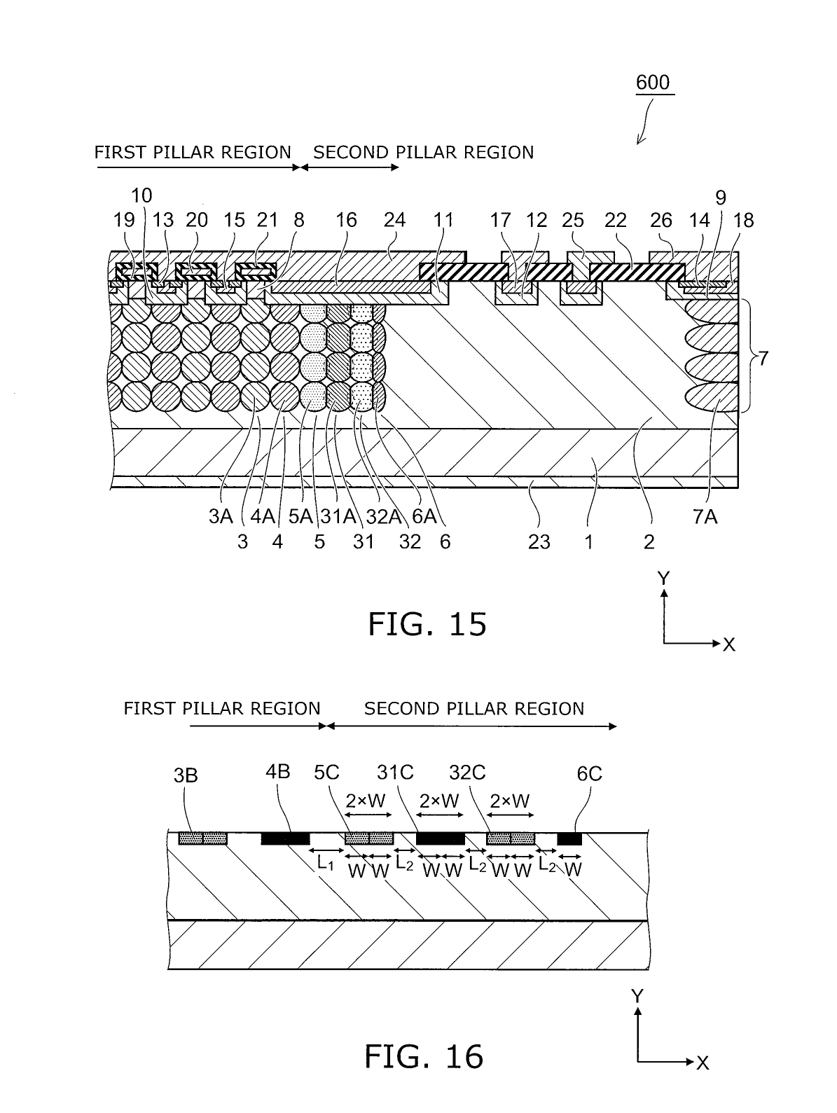

The following is an explanation of a power semiconductor device 600 according to a sixth embodiment using FIGS. 15 and 16. FIG. 15 is a schematic cross-sectional view of the main parts of the power semiconductor device according to the sixth embodiment. FIG. 16 illustrates a part of the manufacturing process of the power semiconductor device according to the sixth embodiment, and is a schematic cross-sectional view of the main parts corresponding to FIG. 2B. Portions having the same constitution as the constitution explained in the fifth embodiment use the same reference number or symbol, and their explanation is omitted. The explanation is mainly the points of difference from the fifth embodiment.

A MOSFET 600 according to this embodiment includes the high resistance epitaxial layer 2 that includes the first pillar region and the second pillar region as an n⁻-type drift layer, the same as for the MOSFET 500 according to the fifth embodiment, but differs from the MOSFET 500 according to the fifth embodiment in the following points.

As illustrated in FIG. 15, the MOSFET 600 according to this embodiment has the structure in which the n-type fifth pillar 31 and the p-type sixth pillar 32 are inserted between the n-type third pillar 3 and the p-type fourth pillar 4 in the second pillar region in the MOSFET 500 according to the fifth embodiment. The MOSFET 600 according to this embodiment differs from the MOSFET 500 according to the fifth embodiment in this respect, but otherwise has the same structure. The p-type fifth pillar 31 is adjacent to the n-type third pillar 5, and the p-type impurity diffused layer 31A of the p-type fifth pillar 31 and the impurity diffused layer 5A of the n-type third pillar 5 overlap in the diffusion layer formation layer 80 similar to the other pillars, and have a third impurity compensation region. Also, the p-type fifth pillar 31 is adjacent to the n-type sixth pillar 32, and the p-type impurity diffused layer 31A of the p-type fifth pillar 31 and the impurity diffused layer 32A of the n-type sixth pillar 32 likewise overlap, and have a fourth impurity compensation region. In addition, the n-type sixth pillar 32 is adjacent to the p-type fourth pillar 6, and the n-type impurity diffused layer 32A of the n-type sixth pillar 32 and the impurity diffused layer 6A of the p-type fourth pillar 6 likewise overlap, and have a fifth impurity compensation region.

In the second pillar region, respective impurity injection layers 5C, 31C, 32C, and 6C of the third pillar 5, the fifth pillar 31, the sixth pillar 32, and the fourth pillar 6 are formed as illustrated in the portion of the manufacturing process of the first pillar region and the second pillar region as illustrated in FIG. 16. The widths of the n-type impurity injection layer 5C of the third pillar 5, the p-type impurity injection layer 31C of the fifth pillar 31, and the n-type impurity injection layer 32C of the sixth pillar 32 are each the same 2×W. The width of the p-type impurity injection layer 6C of the fourth pillar is half the width of these, or W. Also, the gap L2 between adjacent impurity injection layers in the second pillar region is narrower than the gap L1 between the n-type impurity injection layer 3B of the first pillar 3 and the p-type impurity injection layer 4B of the second pillar 4 in the first pillar region, similar to the fifth embodiment.

By setting the widths of the impurity injection layers as described above, the widths in the X direction of the third impurity compensation region, the fourth impurity compensation region, and the fifth impurity compensation region are wider than the width in the X direction of the first impurity compensation region. Therefore, as a result of impurity compensation in each impurity compensation region, the net quantity of n-type impurities in the n-type impurity diffused layer 5A of the third pillar 5 is less than the net quantity of n-type impurities in the n-type impurity diffused layer 3A of the first pillar 3 and the net quantity of p-type impurities in the p-type impurity diffused layer 4A of the second pillar 4. The net quantity of p-type impurities in the p-type impurity diffused layer 6A of the fourth pillar 6 is less than the net quantity of n-type impurities in the n-type impurity diffused layer 5A of the third pillar 5. The net quantity of p-type impurities in the p-type impurity diffused layer 31A of the fifth pillar 31 and the net quantity of n-type impurities in the n-type impurity diffused layer 32A of the sixth pillar 32 are equal, and less than the net quantity of n-type impurities in the n-type impurity diffused layer 5A of the third pillar 5 and greater than the net quantity of p-type impurities in the p-type impurity diffused layer 6A of the fourth pillar 6.

In this embodiment, similar to the fifth embodiment, in the second pillar region at the portion D where adjacent n-type pillars and p-type pillars are in opposition, the net quantity of n-type impurities in the n-type impurity diffused layer of the n-type pillars and the net quantity of p-type impurities in the p-type impurity diffused layer of the p-type pillars are set to be lower than the net quantity of n-type impurities in the n-type impurity diffused layer 3A of the n-type first pillar 3 and the net quantity of p-type impurities in the p-type impurity diffused layer 4A of the p-type second pillar 4 of the first pillar region, while maintaining the equality of the net quantity of the n-type impurities and the net quantity of the p-type impurities. Therefore, as illustrated in FIG. 5, in the portion D where the n-type pillar and the p-type pillar are in opposition in the second pillar region, depletion layers can spread more easily than in the portion B where the n-type first pillar 3 and the p-type second pillar 4 are in opposition in the first pillar region, so the withstand voltage is further increased. If the variation in the width of the apertures of the mask for forming the p-type pillars is restricted to be within the area where the withstand voltage of the portion D where adjacent n-type pillars and p-type pillars are in opposition in the second pillar region is higher than the withstand voltage of the portion B where the first pillar 3 and the second pillar 4 are in opposition in the first pillar region, then breakdown will always occur first in the first pillar region before the second pillar region. The MOSFET 600 according to this embodiment can suppress the reduction in withstand voltage in the termination region due to manufacturing variation in the manufacture of the super junction structure, similar to the MOSFET 500 according to the fifth embodiment, so the avalanche resistance is improved.

The MOSFET 600 according to this embodiment is a structure in which the width of the n-type impurity injection layer 5B of the third pillar 5, the width of the p-type impurity injection layer 31B of the fifth pillar 31, and the width of the n-type impurity injection layer 32B of the sixth pillar 32 are each set to 2×W, the width of the p-type impurity injection layer 6B of the fourth pillar is set to W, and the gap L2 between the impurity injection layers of the adjacent pillars in the second pillar region is set to be narrower than the gap L1 between the impurity injection layer 3B of the first pillar 3 and the impurity injection layer 4B of the second pillar 4 in the first pillar region, in the MOSFET 200 according to the second embodiment. Therefore, it is possible to have the same settings also in the third embodiment and the fourth embodiment. In other words, it is possible to set the width of the impurity injection layer of each pillar in the second pillar region to be the same width as the width of the n-type impurity injection layer 3B of the first pillar 3 and the width of the p-type impurity injection layer 4B of the second pillar 4 in the first pillar region. Also, it is possible to set the width of the impurity injection layer 60B of the fourth pillar 60 to be half the width of the n-type impurity injection layer 3B of the first pillar 3 and the width of the p-type impurity injection layer 4B of the second pillar 4 in the first pillar region. In this case, the gap L2 in the X direction between the impurity injection layers of the second pillar region is set to be narrower than the gap L1 between the impurity injection layer 3B of the first pillar 3 and the impurity injection layer 4B of the second pillar 4 in the first pillar region.

In the third embodiment, when setting as described above, there is the first impurity compensation region in the overlapping portion in the X direction of the impurity diffused layer 3A of the first pillar 3 and the impurity diffused layer 4A of the second pillar 4. There is the third impurity compensation region in the overlapping portion in the X direction of the impurity diffused layer 5A of the third pillar 5 and the impurity diffused layer 31A of the fifth pillar 31. There is the sixth impurity compensation region in the overlapping portion in the X direction of the impurity diffused layer 31A of the fifth pillar 31 and the impurity diffused layer 60A of the fourth pillar 6. The widths in the X direction of the third impurity compensation region and the sixth impurity compensation region are wider than the width in the X direction of the first impurity compensation region. Therefore, as a result of impurity compensation in the impurity compensation regions, the net quantity of n-type (the conductivity type of the third pillar) impurities in the impurity diffused layer 5A of the third pillar 5 is less than the net quantity of n-type impurities in the n-type impurity diffused layer 3A of the first pillar 3 and the net quantity of p-type impurities in the p-type impurity diffused layer 4A of the second pillar 4. The net quantity of n-type impurities in the n-type impurity diffused layer 60A of the fourth pillar 60 is less than the net quantity of n-type impurities in the n-type impurity diffused layer 5A of the third pillar 5. The net quantity of p-type impurities in the p-type impurity diffused layer 31A of the fifth pillar 31 is less than the net quantity of n-type impurities in the n-type impurity diffused layer 5A of the third pillar 5, and greater than the net quantity of n-type impurities in the n-type impurity diffused layer 60A of the fourth pillar 60.

In the fourth embodiment, when setting as described above, there is the first impurity compensation region in the overlapping portion in the X direction of the impurity diffused layer 3A of the first pillar 3 and the p-type impurity diffused layer 4A of the second pillar 4. There is the third impurity compensation region in the overlapping portion in the X direction of the n-type impurity diffused layer 5A of the third pillar 5 and the p-type impurity diffused layer 31A of the fifth pillar 31. There is the fourth impurity compensation region in the overlapping portion in the X direction of the p-type impurity diffused layer 31A of the fifth pillar 31 and the n-type impurity diffused layer 32A of the sixth pillar 32. There is the seventh impurity compensation region in the overlapping portion in the X direction of the n-type impurity diffused layer 32A of the sixth pillar 32 and the p-type impurity diffused layer 33A of the seventh pillar 33. There is the eighth impurity compensation region in the overlapping portion in the X direction of the p-type impurity diffused layer 33A of the seventh pillar 33 and the n-type impurity diffused layer 60A of the fourth pillar 60. The widths in the X direction of the third impurity compensation region, the fourth impurity compensation region, the seventh impurity compensation region, and the eighth impurity compensation region are wider than the width in the X direction of the first impurity compensation region. Therefore, as a result of impurity compensation in the impurity compensation regions, the net quantity of n-type impurities in the n-type impurity diffused layer 5A of the third pillar 5 is less than the net quantity of n-type impurities in the n-type impurity diffused layer 3A of the first pillar 3 and the net quantity of p-type impurities in the p-type impurity diffused layer 4A of the second pillar 4. The net quantity of n-type impurities in the n-type impurity diffused layer 60A of the fourth pillar 60 is less than the net quantity of n-type impurities in the n-type impurity diffused layer 5A of the third pillar 5. The net quantity of p-type impurities in the p-type impurity diffused layer 31A of the fifth pillar 31, the net quantity of n-type impurities in the n-type impurity diffused layer 32A of the sixth pillar 32, and the net quantity of p-type impurities in the p-type impurity diffused layer 33A of the seventh pillar 33 are less than the net quantity of n-type impurities in the n-type impurity diffused layer 5A of the third pillar 5, and greater than the net quantity of n-type impurities in the n-type impurity diffused layer 60A of the fourth pillar 60.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A power semiconductor device, comprising:
a first semiconductor layer of a first conductivity type having a first surface and a second surface on a side opposite to the first surface;
a high resistance epitaxial layer provided on the first surface of the first semiconductor layer, having a first pillar region and a second pillar region;
a second semiconductor layer of a second conductivity type selectively provided on a surface of the first pillar region;
a third semiconductor layer of the first conductivity type selectively provided on a surface of the second semiconductor layer;
a gate electrode provided on the first pillar region, the second semiconductor layer, and the third semiconductor layer via a gate insulating film;
a first electrode electrically connected to the second surface of the first semiconductor layer; and
a second electrode electrically connected to the second semiconductor layer and the third semiconductor layer, and insulated from the gate electrode via an inter-layer insulating film, wherein
the first pillar region includes
a plurality of first pillars of the first conductivity type and a plurality of second pillars of the second conductivity type disposed alternately along a first direction parallel to the first surface of the first semiconductor layer, and one of the plurality of second pillars of the second conductivity type is connected to the second semiconductor layer of the second conductivity type,
the termination of the first pillar region along the first direction ends with either a first pillar or a second pillar,
the second pillar region is adjacent to the first pillar region along the first direction via the termination,
the second pillar region includes
a third pillar having a conductivity type that is the opposite to the conductivity type of the pillar at the termination of the first pillar region, at an end on the first pillar region side along the first direction,
a fourth pillar of a conductivity type opposite to the conductivity type of the third pillar, disposed at another end opposite to the first pillar region side along the first direction,
the plurality of first pillars, the plurality of second pillars, the third pillar, and the fourth pillar are each constituted from a plurality of impurity diffused layers disposed along a second direction normal to the first surface of the first semiconductor layer,
the impurity diffused layers of the plurality of first pillars, the plurality of second pillars, the third pillar, and the fourth pillar are disposed within a single layer parallel to the first surface of the first semiconductor layer,
within the single layer, a net quantity of impurities of the conductivity type of the third pillar in the impurity diffused layer of the third pillar is less than a net quantity of impurities of the first conductivity type in each impurity diffused layer of the plurality of first pillars and a net quantity of the impurities of the second conductivity type in each impurity diffused layer of the plurality of second pillars, and
within the single layer, a net quantity of impurities of the conductivity type of the fourth pillar in the impurity diffused layer of the fourth pillar is less than the net quantity of impurities of the conductivity type of the third pillar in the impurity diffused layer of the third pillar.

2. The device according to claim 1, further comprising in the second pillar region between the third pillar and the fourth pillar, at least a fifth pillar of a conductivity type that is the same as the conductivity type of the fourth pillar, disposed adjacent to the third pillar, and a sixth pillar of a conductivity type that is the same as the conductivity type of the third pillar, disposed adjacent to the fifth pillar, wherein
the fifth pillar and the sixth pillar are constituted from the same number of impurity diffused layers as the third pillar and the fourth pillar, and
within the single layer, a net quantity of impurities of the conductivity type of the fifth pillar in the impurity diffused layer of the fifth pillar and a net quantity of impurities of the conductivity type of the sixth pillar in the impurity diffused layer of the sixth pillar are each less than the net quantity of impurities of the conductivity type of the third pillar in the impurity diffused layer of the third pillar, and greater than the net quantity of the impurities of the conductivity type of the fourth pillar in the impurity diffused layer of the fourth pillar.

3. A power semiconductor device, comprising: a first semiconductor layer of a first conductivity type having a first surface and a second surface on a side opposite to the first surface;
a high resistance epitaxial layer provided on the first surface of the first semiconductor layer, having a first pillar region and a second pillar region;
a second semiconductor layer of a second conductivity type selectively provided on a surface of the first pillar region;
a third semiconductor layer of the first conductivity type selectively provided on a surface of the second semiconductor layer;
a gate electrode provided on the first pillar region, the second semiconductor layer, and the third semiconductor layer with via a gate insulating film;
a first electrode electrically connected to the second surface of the first semiconductor layer; and
a second electrode electrically connected to the second semiconductor layer and the third semiconductor layer, and insulated from the gate electrode via an inter-layer insulating film, wherein
the first pillar region includes a plurality of first pillars of the first conductivity type and a plurality of second pillars of the second conductivity type disposed alternately along a first direction parallel to the first surface of the first semiconductor layer,
the termination of the first pillar region along the first direction ends with either a first pillar or a second pillar,
the second pillar region is adjacent to the first pillar region along the first direction via the termination,
the second pillar region includes,
a third pillar having a conductivity type that is the opposite to the conductivity type of the pillar at the termination of the first pillar region, at an end along the first direction on the first pillar region side,
a fourth pillar of a conductivity type that is the same as the conductivity type of the third pillar, disposed at another end along the first direction opposite to the first pillar region, and
a fifth pillar of a conductivity type that is the opposite to the conductivity type of the third pillar, disposed adjacent to the third pillar,
the plurality of first pillars, the plurality of second pillars, the third pillar, the fourth pillar, and the fifth pillar are each constituted from a plurality of impurity diffused layers disposed along a second direction normal to the first surface of the first semiconductor layer,
the impurity diffused layers of the plurality of first pillars, the plurality of second pillars, the third pillar, the fourth pillar, and the fifth pillar are disposed within a single layer parallel to the first surface of the first semiconductor layer,
within the single layer, a net quantity of impurities of the conductivity type of the third pillar in the impurity diffused layer of the third pillar is less than a net quantity of impurities of the first conductivity type in each impurity diffused layer of the plurality of first pillars and a net quantity of the impurities of the second conductivity type in each impurity diffused layer of the plurality of second pillars,
within the single layer, a net quantity of impurities of the conductivity type of the fourth pillar in the impurity diffused layer of the fourth pillar is less than the net quantity of impurities of the conductivity type of the third pillar in the impurity diffused layer of the third pillar, and
within the single layer, a net quantity of impurities of the conductivity type of the fifth pillar in the impurity diffused layer of the fifth pillar is less than the net quantity of impurities of the conductivity type of the third pillar in the impurity diffused layer of the third pillar, and greater than the net quantity of impurities of the conductivity type of the fourth pillar in the impurity diffused layer of the fourth pillar.

4. The device according to claim 3, further comprising in the second pillar region between the fourth pillar and the fifth pillar, at least a sixth pillar of a conductivity type that is the opposite to the conductivity type of the fifth pillar, disposed adjacent to the fifth pillar, and a seventh pillar of a conductivity type that is the same as the conductivity type of the fifth pillar, disposed adjacent to the sixth pillar, wherein
the sixth pillar and the seventh pillar are constituted from the same number of impurity diffused layers as the third pillar and the fourth pillar, and
within the single layer, a net quantity of impurities of the conductivity type of the sixth pillar in the impurity diffused layer of the sixth pillar and a net quantity of impurities of the conductivity type of the seventh pillar in the impurity diffused layer of the seventh pillar are each less than the net quantity of impurities of the conductivity type of the third pillar in the impurity diffused layer of the third pillar, and greater than the net quantity of the impurities of the conductivity type of the fourth pillar in the impurity diffused layer of the fourth pillar.

5. The device according to claim 1, wherein within the single layer, a gross quantity of impurities of the conductivity type of the third pillar in the impurity diffused layer of the third pillar is less than a gross quantity of impurities of the first conductivity type in each impurity diffused layer of the plurality of first pillars and a gross quantity of impurities of the second conductivity type in each impurity diffused layer of the plurality of second pillars, and
within the single layer, a gross quantity of impurities of the conductivity type of the fourth pillar in the impurity diffused layer of the fourth pillar is less than the gross quantity of impurities of the conductivity type of the third pillar in the impurity diffused layer of the third pillar.

6. The device according to claim 2, wherein within the single layer, a gross quantity of impurities of the conductivity type of the third pillar in the impurity diffused layer of the third pillar is less than a gross quantity of impurities of the first conductivity type in each impurity diffused layer of the plurality of first pillars and a gross quantity of impurities of the second conductivity type in each impurity diffused layer of the plurality of second pillars,
within the single layer, a gross quantity of impurities of the conductivity type of the fourth pillar in the impurity diffused layer of the fourth pillar is less than the gross quantity of impurities of the conductivity type of the third pillar in the impurity diffused layer of the plurality of the third pillar, and
within the single layer, a gross quantity of impurities of the conductivity type of the fifth pillar in the impurity diffused layer of the fifth pillar and a gross quantity of impurities of the conductivity type of the sixth pillar in the impurity diffused layer of the sixth pillar are less than the gross quantity of impurities of the conductivity type of the third pillar in the impurity diffused layer of the third pillar, and greater than the gross quantity of impurities of the conductivity type of the fourth pillar in the impurity diffused layer of the fourth pillar.

7. The device according to claim 3, wherein within the single layer, a gross quantity of impurities of the conductivity type of the third pillar in the impurity diffused layer of the third pillar is less than a gross quantity of impurities of the first conductivity type in each impurity diffused layer of the plurality of first pillars and a gross quantity of impurities of the second conductivity type in each impurity diffused layer of the plurality of second pillars,
within the single layer, a gross quantity of impurities of the conductivity type of the fourth pillar in the impurity diffused layer of the fourth pillar is less than the gross quantity of impurities of the conductivity type of the third pillar in the impurity diffused layer of the third pillar, and
within the single layer, a gross quantity of impurities of the conductivity type of the fifth pillar in the impurity diffused layer of the fifth pillar is less than the gross quantity of impurities of the conductivity type of the third pillar in the impurity diffused layer of the third pillar, and greater than the gross quantity of impurities of the conductivity type of the fourth pillar in the impurity diffused layer of the fourth pillar.

8. The device according to claim 4, wherein within the single layer, a gross quantity of impurities of the conductivity type of the third pillar in the impurity diffused layer of the third pillar is less than a gross quantity of impurities of the first conductivity type in each impurity diffused layer of the plurality of first pillars and a gross quantity of impurities of the second conductivity type in each impurity diffused layer of the plurality of second pillars,
within the single layer, a gross quantity of impurities of the conductivity type of the fourth pillar in the impurity diffused layer of the fourth pillar is less than the gross quantity of impurities of the conductivity type of the third pillar in the impurity diffused layer of the third pillar,
within the single layer, a gross quantity of impurities of the conductivity type of the fifth pillar in the impurity diffused layer of the fifth pillar is less than the gross quantity of impurities of the conductivity type of the third pillar in the impurity diffused layer of the third pillar, and greater than the gross quantity of impurities of the conductivity type of the fourth pillar in the impurity diffused layer of the fourth pillar, and
within the single layer, a gross quantity of impurities of the conductivity type of the sixth pillar in the impurity diffused layer of the sixth pillar and a gross quantity of impurities of the conductivity type of the seventh pillar in the impurity diffused layer of the seventh pillar are less than the gross quantity of impurities of the conductivity type of the third pillar in the impurity diffused layer of the third pillar, and greater than the gross quantity of impurities of the conductivity type of the fourth pillar in the impurity diffused layer of the fourth pillar.

9. The device according to claim 5, wherein within the single layer, the gross quantity of impurities of the conductivity type of the fourth pillar in the impurity diffused layer of the fourth pillar is less than half the gross quantity of impurities of the first conductivity type in each impurity diffused layer of the plurality of first pillars and less than half the gross quantity of impurities of the second conductivity type in each impurity diffused layer of the plurality of second pillars.

10. The device according to claim 7, wherein within the single layer, the gross quantity of impurities of the conductivity type of the fourth pillar in the impurity diffused layer of the fourth pillar is less than half the gross quantity of impurities of the first conductivity type in each impurity diffused layer of the plurality of first pillars and less than half the gross quantity of impurities of the second conductivity type in each impurity diffused layer of the plurality of second pillars.

11. The device according to claim 1, wherein the single layer includes:
a first impurity compensation region in which impurities of the first conductivity type and impurities of the second conductivity type are mixed in a portion where each of the impurity diffused layers of the plurality of first pillars and each of the impurity diffused layers of the plurality of second pillars overlap with each other in the first direction,
a second impurity compensation region in which impurities of the first conductivity type and impurities of the second conductivity type are mixed in a portion where the impurity diffused layer of the third pillar and the impurity diffused layer of the fourth pillar overlap with each other in the first direction, wherein
a width in the first direction of the second impurity compensation region is greater than a width in the first direction of the first impurity compensation region.

12. The device according to claim 2, wherein the single layer includes:
a first impurity compensation region in which impurities of the first conductivity type and impurities of the second conductivity type are mixed in a portion where each of the impurity diffused layers of the plurality of first pillars and each of the impurity diffused layers of the plurality of second pillars overlap with each other in the first direction,
a third impurity compensation region in which impurities of the first conductivity type and impurities of the second conductivity type are mixed in a portion where the impurity diffused layer of the third pillar and the impurity diffused layer of the fifth pillar overlap with each other in the first direction,
a fourth impurity compensation region in which impurities of the first conductivity type and impurities of the second conductivity type are mixed in a portion where the impurity diffused layer of the fifth pillar and the impurity diffused layer of the sixth pillar overlap with each other in the first direction, and
a fifth impurity compensation region in which impurities of the first conductivity type and impurities of the second conductivity type are mixed in a portion where the impurity diffused layer of the sixth pillar and the impurity diffused layer of the fourth pillar overlap with each other in the first direction, wherein
widths in the first direction of the third impurity compensation region, the fourth impurity compensation region, and the fifth impurity compensation region are each greater than a width in the first direction of the first impurity compensation region.

13. The device according to claim 3, wherein the single layer includes:
a first impurity compensation region in which impurities of the first conductivity type and impurities of the second conductivity type are mixed in a portion where each of the impurity diffused layers of the plurality of first pillars and each of the impurity diffused layers of the plurality of second pillars overlap with each other in the first direction,
a third impurity compensation region in which impurities of the first conductivity type and impurities of the second conductivity type are mixed in a portion where the impurity diffused layer of the third pillar and the impurity diffused layer of the fifth pillar overlap with each other in the first direction, and
a sixth impurity compensation region in which impurities of the first conductivity type and impurities of the second conductivity type are mixed in a portion where the impurity diffused layer of the fifth pillar and the impurity diffused layer of the fourth pillar overlap with each other in the first direction, wherein
widths in the first direction of the third impurity compensation region and the sixth impurity compensation region are each greater than a width in the first direction of the first impurity compensation region.

14. The device according to claim 4, wherein the single layer includes:
a first impurity compensation region in which impurities of the first conductivity type and impurities of the second conductivity type are mixed in a portion where each of the impurity diffused layers of the plurality of first pillars and each of the impurity diffused layers of the plurality of second pillars overlap with each other in the first direction,
a third impurity compensation region in which impurities of the first conductivity type and impurities of the second conductivity type are mixed in a portion where the impurity diffused layer of the third pillar and the impurity diffused layer of the fifth pillar overlap with each other in the first direction,
a fourth impurity compensation region in which impurities of the first conductivity type and impurities of the second conductivity type are mixed in a portion where the impurity diffused layer of the fifth pillar and the impurity diffused layer of the sixth pillar overlap with each other in the first direction,
a seventh impurity compensation region in which impurities of the first conductivity type and impurities of the second conductivity type are mixed in a portion where the impurity diffused layer of the sixth pillar and the impurity diffused layer of the seventh pillar overlap with each other in the first direction, and
an eighth impurity compensation region in which impurities of the first conductivity type and impurities of the second conductivity type are mixed in a portion where the impurity diffused layer of the seventh pillar and the impurity diffused layer of the fourth pillar overlap with each other in the first direction, wherein
widths in the first direction of the third impurity compensation region, the fourth impurity compensation region, the seventh impurity compensation region, and the eighth impurity compensation layer are each greater than a width in the first direction of the first impurity compensation region.

15. The device according to claim 10, wherein in the single layer, the gross quantity of impurities of the conductivity type of the fourth pillar in the impurity diffused layer of the fourth pillar is half the gross quantity of impurities in each of the impurity diffused layers of the plurality of first pillars and half the gross quantity of impurities in each of the impurity diffused layers of the plurality of second pillars.

16. The device according to claim 12, wherein in the single layer, the gross quantity of impurities of the conductivity type of the fourth pillar in the impurity diffused layer of the fourth pillar is half the gross quantity of impurities in each of the impurity diffused layers of the plurality of first pillars and half the gross quantity of impurities in each of the impurity diffused layers of the plurality of second pillars.
